(19) United States
(12) Patent Application Publication
(10) Pub. No.: US 2026/0370253 A1
(43) Pub. Date: Nov. 19, 2026

(54) TRANSFORM-BASED BLOCK-WISE CODING

(71) Applicant: Fraunhofer-Gesellschaft zur Förderung der angewandten Forschung e.V., München (DE)

(72) Inventors: Jonathan PFAFF, Berlin (DE); Heiner KIRCHHOFFER, Berlin (DE); Christian HELMRICH, Berlin (DE); Sophie PIENTKA, Berlin (DE); Christian RUDAT, Berlin (DE); Heiko SCHWARZ, Berlin (DE); Detlev MARPE, Berlin (DE); Thomas WIEGAND, Berlin (DE)

(73) Assignee: Fraunhofer-Gesellschaft zur Förderung der angewandten Forschung e.V., München (DE)

(21) Appl. No.: 19/738,508

(22) Filed: Jul. 12, 2026

Related U.S. Application Data
(63) Continuation of application No. PCT/EP2025/050709, filed on Jan. 13, 2025.

(30) Foreign Application Priority Data
Jan. 12, 2024 (EP) 24151740.8
Oct. 21, 2024 (EP) 24207895.4

(51) Int. Cl. H04B 1/66; H03M 7/30

(52) U.S. Cl. CPC H04B 1/662; H03M 7/3073; H03M 7/6005; H03M 7/6011

(57) ABSTRACT

A decoder for decoding a digital time-varying signal from a data stream is presented. The decoder is configured to decode the digital time-varying signal from the data stream in non-overlapping temporal blocks by decoding each of transform-coded temporal blocks of the non-overlapping temporal blocks of the digital time-varying signal by predicting the respective transform-coded temporal block using a selected prediction mode out of a set of prediction modes to obtain a prediction signal, decoding coefficients from the data stream, the coefficients representing a prediction residual signal of the respective transform-coded temporal block in a transform domain, subjecting the coefficients to a predetermined re-transformation from the transform domain to time domain to obtain a time-domain prediction residual signal representing a prediction residual signal of the respective transform-coded temporal block in a time domain, and correcting the prediction signal using the time-domain prediction residual signal, wherein the predetermined re-transformation is a non-overlapping transform.

### CROSS-REFERENCE TO RELATED APPLICATION

This application is a continuation of copending International Application No. PCT/EP2025/050709, filed Jan. 13, 2025, which is incorporated herein by reference in its entirety, and additionally claims priority from European Applications Nos. EP 24 151 740.8, filed Jan. 12, 2024, and EP 24 207 895.4, Oct. 21, 2024, all of which are incorporated herein by reference in its entirety

Embodiments according to the invention relate to a decoder and an encoder for decoding a digital time-varying signal, in particular for decoding transform-coded temporal blocks thereof.

### BACKGROUND OF THE INVENTION

Digital time-varying signals are commonly used for representation of various data such as biomedical signals or seismic measurements. However, coding techniques may suffer a delay between encoder and decoder, as well as high coding complexity. Furthermore, there is an ever increasing demand for coding accuracy and coding compression. There is a need for finding a compromise between coding compression and coding accuracy of such digital time-varying signals.

### SUMMARY

An embodiment may have a decoder for decoding a digital time-varying signal from a data stream, configured to decode the digital time-varying signal from the data stream in non-overlapping temporal blocks by decoding each of transform-coded temporal blocks of the non-overlapping temporal blocks of the digital time-varying signal by predicting the respective transform-coded temporal block using a selected prediction mode out of a set of prediction modes to acquire a prediction signal, decoding coefficients from the data stream, the coefficients representing a prediction residual signal of the respective transform-coded temporal block in a transform domain, subjecting the coefficients to a predetermined re-transformation from the transform domain to time domain to acquire a time-domain prediction residual signal representing a prediction residual signal of the respective transform-coded temporal block in a time domain, and correcting the prediction signal using the time-domain prediction residual signal, wherein the predetermined re-transformation is a non-overlapping transform.

Another embodiment may have an encoder for encoding a digital time-varying signal into a data stream, configured to encode the digital time-varying signal into the data stream in non-overlapping temporal blocks by encoding each of transform-coded temporal blocks of the non-overlapping temporal blocks of the digital time-varying signal by predicting the respective transform-coded temporal block using a selected prediction mode out of a set of prediction modes to acquire a prediction signal, subjecting a time-domain prediction residual signal representing a prediction residual signal of the respective transform-coded temporal block in a time domain to a predetermined transformation from the time domain to a transform domain to acquire coefficients representing the prediction residual signal of the respective transform-coded temporal block in the transform domain, and encoding the coefficients into the data stream so as to be used for correcting the prediction signal, wherein the predetermined transformation is a non-overlapping transform.

Another embodiment may have a method for decoding for decoding a digital time-varying signal from a data stream, the method comprising decoding the digital time-varying signal from the data stream in non-overlapping temporal blocks by decoding each of transform-coded temporal blocks of the non-overlapping temporal blocks of the digital time-varying signal by predicting the respective transform-coded temporal block using a selected prediction mode out of a set of prediction modes to acquire a prediction signal, decoding coefficients from the data stream, the coefficients representing a prediction residual signal of the respective transform-coded temporal block in a transform domain, subjecting the coefficients to a predetermined re-transformation from the transform domain to time domain to acquire a time-domain prediction residual signal representing a prediction residual signal of the respective transform-coded temporal block in a time domain, and correcting the prediction signal using the time-domain prediction residual signal, wherein the predetermined re-transformation is a non-overlapping transform.

Another embodiment may have a method for encoding a digital time-varying signal into a data stream, configured to encode the digital time-varying signal into the data stream in non-overlapping temporal blocks by encoding each of transform-coded temporal blocks of the non-overlapping temporal blocks of the digital time-varying signal by predicting the respective transform-coded temporal block using a selected prediction mode out of a set of prediction modes to acquire a prediction signal, subjecting a time-domain prediction residual signal representing a prediction residual signal of the respective transform-coded temporal block in a time domain to a predetermined transformation from the time domain to a transform domain to acquire coefficients representing the prediction residual signal of the respective transform-coded temporal block in the transform domain, and encoding the coefficients into the data stream so as to be used for correcting the prediction signal, wherein the predetermined transformation is a non-overlapping transform.

Another embodiment may have a data stream encoded using the method for encoding according to the present invention.

Another embodiment may have a non-transitory digital storage medium having a computer program stored thereon to perform the methods of the present invention when said computer program is run by a computer.

In accordance with a first aspect of the present invention, a decoder for decoding a digital time-varying signal from a data stream is presented. The decoder is configured to decode the digital time-varying signal from the data stream in non-overlapping temporal blocks by decoding each of transform-coded temporal blocks of the non-overlapping temporal blocks of the digital time-varying signal by predicting the respective transform-coded temporal block using a selected prediction mode out of a set of prediction modes to obtain a prediction signal, decoding coefficients from the data stream, the coefficients representing a prediction residual signal of the respective transform-coded temporal block in a transform domain, subjecting the coefficients to a predetermined re-transformation from the transform domain to time domain to obtain a time-domain prediction residual signal representing a prediction residual signal of the respective transform-coded temporal block in a time domain, and correcting the prediction signal using the time-domain prediction residual signal, wherein the predetermined re-transformation is a non-overlapping transform.

The transformation and retransformation allows representing and coding data in a more energy dense manner, which improves coding efficiency. Prediction signals can be derived from already decoded samples, wherein the prediction signal can be corrected by the prediction residual signal, which allows reducing the amount of data that needs to be coded and signaled. It has been recognized that the use of non-overlapping transforms allow reconstruction of temporal blocks without depending on an overlap (e.g., signal overlap) from neighboring temporal blocks. As a result, reconstruction can be completed earlier and a delay between encoder and decoder can be reduced. Furthermore, the coding of non-overlapping transforms can be performed with less complexity and can be less prone to errors.

Furthermore, coding flexibility may be improved, since non-overlapping transforms can be compatible with deblocking algorithms that do not rely on a formation of overlapping frame signals. Since the transforms do not overlap, a deblocking can be performed individually for a temporal block, without necessarily affecting (and/or delaying) a deblocking and/or decoding a neighboring block. For example, a deblocking of a previously decoded block may affect its overlap (e.g., signal overlap) with the currently decoded block, which may reduce coding accuracy (e.g., due to deviations in the signal overlap introduced by deblocking) or coding speed. The decoder may, for example, receive deblocking parameters for a current block and can perform a deblocking only for that block, which can reduce a decoding delay and may reduce of the formation of signal deviations that could be formed by the deblocking when combining overlapping signals (e.g., in the time domain). Furthermore, since the transforms do not overlap, an immediately preceding temporal block may be fully reconstructed (as well as deblocked) before coding the subsequent temporal block. As a result, the information of the fully reconstructed temporal block can be used as additional information to improve (and/or reduce signaling for) a deblocking of the currently coded temporal block (e.g., derive one or more deblocking parameters based on the preceding temporal block).

According to another aspect, an encoder for encoding a digital time-varying signal from a data stream is provided. The encoder is configured to encode the digital time-varying signal from the data stream in non-overlapping temporal blocks by encoding each of transform-coded temporal blocks of the non-overlapping temporal blocks of the digital time-varying signal by predicting the respective transform-coded temporal block using a selected prediction mode out of a set of prediction modes to obtain a prediction signal, subjecting a time-domain prediction residual signal representing a prediction residual signal of the respective transform-coded temporal block in a time domain to a predetermined transformation from the time domain to a transform domain to obtain coefficients representing the prediction residual signal of the respective transform-coded temporal block in the transform domain, and encoding the coefficients into the data stream so as to be used for correcting the prediction signal, wherein the predetermined transformation is a non-overlapping transform.

According a further aspect, corresponding methods for decoding and encoding a digital time-varying signal into a data stream are provided.

An embodiment is related to a data stream having a digital-time varying signal (e.g., an audio signal, biometric signal, or seismic signal) encoded thereinto using a herein described method for encoding. The data stream may be stored on a storage medium (e.g., non-transitory storage medium).

An embodiment is related to a computer program (e.g., stored on a storage medium, e.g., non-transitory storage medium, e.g., computer program product) having a program code for performing, when running on a computer, a herein described method, when being executed on the computer.

### BRIEF DESCRIPTION OF THE DRAWINGS

The drawings are not necessarily to scale, emphasis instead generally being placed upon illustrating the principles of the invention. Embodiments of the present invention will be detailed subsequently referring to the appended drawings, in which:

FIG. 1 shows a schematic view of a decoder and decoder for coding a digital time-varying signal from a data stream;

FIG. 2 shows a schematic view of a decoder for decoding a multi-channel digital signal from a data stream;

FIG. 3 shows schematic embodiments for a decoder configured to decode coded channels representing a multi-channel digital signal from the data stream, and an encoder configured to encoder coded channels representing a multi-channel digital signal into the data stream;

FIG. 4A shows a schematic view of a decoder for decoding a digital time-varying signal from a data stream;

FIG. 4B shows a schematic view of an encoder for encoding a digital time-varying signal into a data stream;

FIG. 5 shows a schematic view of decoding a digital time-varying signal from a data stream;

FIG. 6 shows a schematic coding scheme for decoding comprising modifying the time-domain prediction residual signal;

FIG. 7 shows a block diagram of a typical linear predictive coding (LPC) based lossless audio encoder;

FIG. 8A shows a schematic view of an encoding procedure for encoding a digital time-varying signal;

FIG. 8B shows an example of a decoding procedure for decoding a digital time-varying signal;

FIG. 8C shows a schematic view of an example for a set of prediction modes and a selection therefrom;

FIG. 9 shows an example of an encoder and decoder using LPC prediction;

FIG. 10 shows an example of a decoded residual signal without deblocking and with deblocking;

FIG. 11A shows a schematic view of samples of a time-domain prediction residual signal before and after modification using one or more deblocking parameters;

FIG. 11B shows a schematic view of samples of a time-domain prediction residual signal having a cosine-like shape before and after modification using one or more deblocking parameters;

FIG. 12A shows a schematic view of samples of a time-domain prediction residual signal before and after modification using a deblocking parameter and a further deblcoking parameter; and

FIG. 12B shows a schematic view of samples of a time-domain prediction residual signal having a cosine-like shape before and after modification using a deblocking parameter and a further deblcoking parameter.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

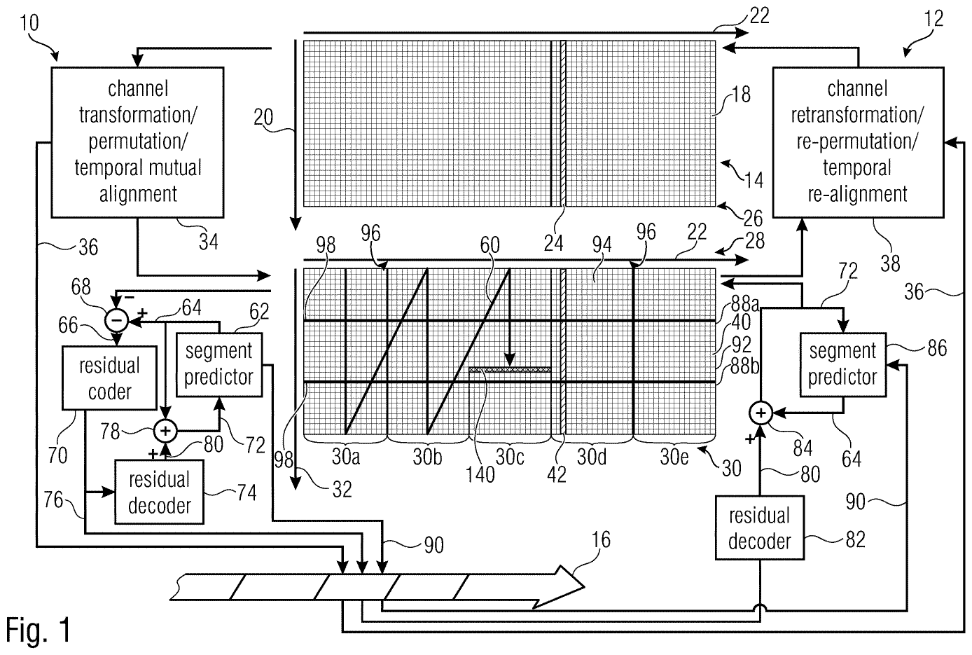

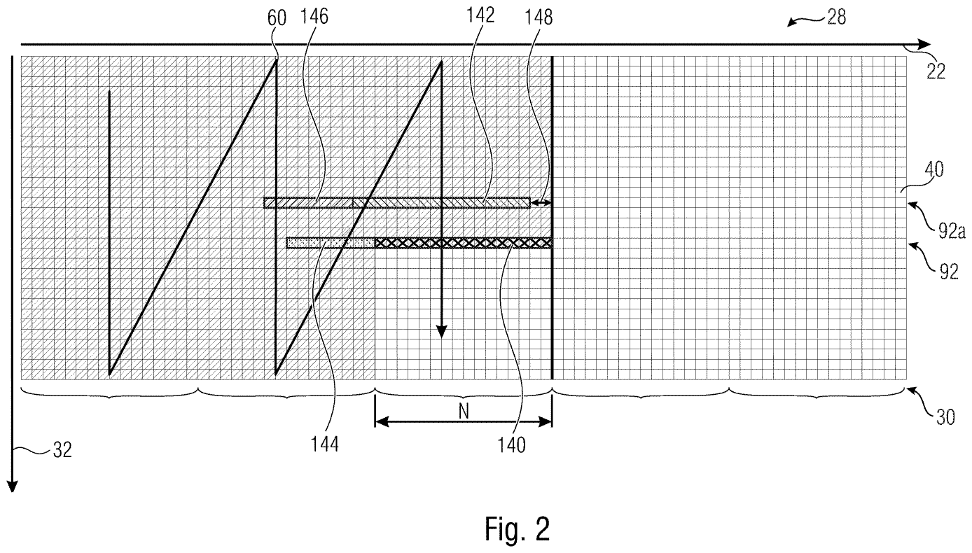

The description proceeds with a presentation of a possible framework or codec into which the embodiments described (e.g., with reference to FIGS. 2 to 11B may be built into. Many details described in this framework are, however, optional when being combined with any of the described embodiments (e.g., with reference to any of FIGS. 2 to 11B. To be more precise, the framework is described with respect to FIG. 1 which shows an encoder for encoding a multi-channel digital signal 14 into a datastream 16 as well as decoder 12 for decoding the multi-channel digital signal 14 from datastream 16. This description of FIG. 1 shall be seen as a presentation of new embodiments of the present application which result when combining any of the embodiments described above or any of the embodiments described subsequently is combined with the decoder 12 or encoder 10 of FIG. 1 either by adopting all details/functionalities described with respect to FIG. 1 or with leaving-out some of the details/functionalities described with respect to FIG. 1. Sometimes such “optional” features of FIG. 1 are explicitly identified as being optional with respect to the combination of the herein described embodiments, but the just-mentioned possible combinations of the subsequently explained embodiments with the description of FIG. 1 shall not be restricted to the these explicitly identified variations of FIG. 1 in terms of leaving-out certain features.

In FIG. 1, the multi-channel digital signal 14 is illustrated by way of an array of samples with the samples (e.g., wherein each sample defines a single value) being illustrated as small squares 18. Each line/row corresponds to a certain channel (e.g., 32 channels in FIG. 1, but a single channel or any other of channels may be used) of the multi-channel digital signal 14. Each channel of signal 14 may have associated therewith a respective channel ID and FIG. 1 shows these channels as being ordered according to their channel ID along vertical axis 20 which, thus, corresponds to a “source” channel axis 20. The horizontal axis 22 corresponds to time (e.g., in absolute time units such as us or in units of samples, which may optionally all have the same duration, e.g., determined by a sampling rate) so that samples 18 forming one column, or being horizontally aligned, are samples belonging to one common time instant. Such set/column of temporally co-located samples 18 is exemplarily illustrated in FIG. 1 at 24.

Each channel, thus, forms a digital time-varying signal or time/amplitude or time-to-amplitude signal. The multi-channel digital signal 14 might have been obtained by at least one of Electrocardiography, Electroencephalography, Electromyography or seismic measurement. Differently speaking, the multi-channel digital signal might be a bio-physiological waveform data (e.g., a signal representative of a heart, brain, or eye activity) such as an electroencephalography (EEG) signal, an electrocardiogram (ECG), or an electromyography (EMG) signal, or seismic waveform data. However, each channel/signal might alternatively be another sort of waveform signal data such as scalar media data such as an audio signal and the signal 14 might be a multi-channel audio signal.

FIG. 1 illustrates the option according to which signal 14 is not coded directly, i.e., in the original domain 26, but in a so-called “coded domain” 28 (e.g., frequency domain) which might differ from the original domain 26 (e.g., time domain) by one or more of 1) channel transformation, 2) channel permutation and 3) temporal mutual channel alignment. The channel transformation, if applied, transforms, per sample time instant, a set or column 24 of samples from domain 26 to domain 28. Thus, in domain 28, the sample pitch and the time axis is the same as in domain 26, but the meaning of the channels is different, i.e., the “source” channels of domain 26 become transformed channels in domain 28. Accordingly, the vertical axis in FIG. 1 for domain 28 is denoted as 32. Note that the channel transformation might leave the number of channels unchanged so that there is the same number of channels in domain 26 as well as domain 28 (e.g., 32 channels in both domains 26, 28), but different approaches are also possible. Generally, the channel transformation would aim at reducing redundancy and trying to condense the channels' energy onto a fewer number of channels in domain 28. As said, the channel transformation is optional. Accordingly, in general terms, the channels in domain 28 are called “coded channels” in order to distinguish them from the “original” or “source” channels of digital signal 14 in domain 26. The permutation is also optional and may be used in combination with, or without, the channel transformation. If used in combination with the channel transformation, the permutation may be performed prior to and/or or subsequent to the channel transformation in order to permute/sort the source channels prior to transformation and the coded channels subsequent to the channel transformation. The channel transformation might be a DCT (discrete cosine transform), DST (discrete sine transform), FFT (fast fourier transform) or any other transformation. The temporal mutual alignment is also optional and might be seen as a constant temporal alignment between the source channels or the coded channels.

The module in encoder 10 performing the one or more of channel transformation, channel permutation and temporal mutual alignment is indicated in FIG. 1 as block 34. Side information 36 might be used in order to signal information on one or more of the following: 1) The channel transformation used, 2) information on the permutation(s) among the source channels and/or coded channels and 3) information on the mutual temporal alignment/delays between the source channels or coded channels wherein the temporal mutual alignment might be restricted to full sample precision. A corresponding block 38 in decoder 12 performs the reverse step, i.e., performs one or more of: 1) a channel retransformation, 2) a re-permutation of the source channels and/or coded channels and 3) a temporal re-alignment of the source channels or coded channels. Note, that if no channel transformation takes place, the coded channels are, in fact, equal to the source channels except for being temporally mutually aligned or being differently sorted due to permutation. Block 38 might be controlled by the before-mentioned side information 36.

Thus, the “actual coding” relates to the coded channels in domain 28. In the coded domain 28, the coded channels are depicted in FIG. 1 as lines or rows of samples 40, each extending along time axis 22, the coded channels being depicted one on top of the other along coded channel axis 32—potentially ordered according to a coded channel ID the have associated therewith—so as to result into an array of samples 40. Again, although FIG. 1 depicts the case that the number of source channels equals the number of coded channels, the number might be different. Further, if channel transformation is used, while there is no longer a clear association between source channels on the one hand and coded channels on the other hand, the temporal association remains: For each temporally co-located samples 24, there is a corresponding temporally co-located set 42 of samples 40 of the coded channels, wherein the set 42 in domain 28 is a column and might be a set of horizontally mutually offset samples in case of, and according to, the mutual temporal alignment, if applied. In case of FIG. 1, it has been assumed that no such temporal alignment took place so that both sets 42 and 24 are pure columns in the time/channel representation.

The actual coding is done in units of so-called temporal blocks 30. The term “temporal block” 30 is used so as to denote both a temporal portion of the multi-channel signal in domain 28, i.e., the set of coded channels, as well as a temporal portion of a certain coded channel. That is, for each temporal block 30, each coded channel has a temporal block such as block 140 depicted for some temporal block 30c and same are mutually co-located. The coding is done sequentially along these blocks 140, by following a coding/decoding order, which traverses the blocks 140 temporal block 30 by temporal block 30 with traversing temporally co-located blocks of the coded channels along a channel order corresponding to the order of the coded channels along axis 32. This coding/decoding order is illustrated in FIG. 1 at 60. That is, in case of temporal block 140 (e.g., temporal channel block) being the block currently to be coded/decoded, the previously decoded/encoded temporal blocks include all preceding temporal blocks of all coded channels as well as the temporally co-located temporal blocks of coded channels preceding the coded channel 92 of temporal block 140 in channel order. These previously coded/decoded temporal blocks and their samples are illustrated in FIG. 1 by way of shading. In this regard, note that in FIG. 1, merely one temporal block 140 has been illustrated explicitly in order to reduce the complexity of FIG. 1. Thus, in the specification herein, reference sign 140 is sometimes used to indicate the currently encoded/decoded temporal block or to stand representatively for all temporal blocks. Further, as depicted in FIG. 1, the partitioning of signal 14 into temporal blocks 30 and 140, respectively, might be done in a manner so that these blocks 30 and 140, respectively, are non-overlapping.

The actual coding in units of the temporal blocks 140 is performed predictively. That is, the encoder 10 comprises a block predictor 62 which predicts the samples of the currently coded temporal block 140, thereby yielding a prediction signal 64, and the prediction residual 66 formed by a subtraction between the actual sample values of temporal block 140 and the predicted samples of prediction signal 64 formed at a subtractor 68 is coded into the datastream 16 by residual coder 70. The residual coding in residual coder 70 may, or may not, involve a coding error by means of quantization. In any case, block predictor 62 uses the reconstructable version as being available by previously coded temporal blocks in order to obtain the prediction signal 64. This reconstructable version 72 might be derived at encoder 10 by means of a residual decoder 74 which reverses potential coding loss, such as quantization by means of dequantization, manifesting itself in the residual signal 76 coded into datastream 16, and an adder 78 which sums-up prediction signal 64 and the reconstructable residual signal 80 as obtained by residual decoder 74.

The decoder 12 decodes the coded channels from data stream 16 in a corresponding manner, i.e., in units of the temporal blocks 30 or in temporal blocks 140, respectively, and using predictive decoding. To this end, the decoder 12 comprises a residual decoder 82, an adder 84 and a block predictor 86 which correspond to, and are mutually connected in the same manner as, elements 74, 78 and 62 of encoder 10. That is, the residual decoder 82 derives from the residual signal 76 in data stream 16 the reconstructable residual signal 80 for a currently decoded temporal block 140 which is then subject to addition with prediction signal 64 derived by block predictor 86 for temporal block 140 on the basis of the reconstructed version 72 of previously decoded temporal blocks at adder 84. The output of adder 84, thus, yields the reconstructed version 72 of the currently decoded temporal block 140 and becomes part of the pool of already decoded samples of previously decoded temporal blocks when the temporal blocks of the coded channels are, in this manner, traversed along coding/decoding order 60 so as to reconstruct the coded channels in the coded domain 28.

In order to enable a high degree of random access capability, some of the temporal blocks 30 may be coded in a random access manner meaning that the coded channels therein are coded independent from previous temporal blocks 30. Imagine, for instance, that temporal blocks 30b and 30e are random access temporal blocks. Then, none of the temporal channel blocks 140 in temporal block 30b as well as 30e would depend on any preceding temporal block 140 such as none temporal block within temporal block 30a forming a coding dependency basis for any temporal channel block 140 in temporal block 30b and none of the temporal channel blocks 140 within temporal blocks 30a to 30d forming a coding dependency basis for any of the temporal channel blocks 140 within temporal block 30e. Thus, in other words, coding dependencies are restricted so as to not reach-out beyond the border of a random access temporal block 30b and 30e towards any preceding temporal block 30. Such restriction might also hold for intermediate temporal blocks 30c to 30d between random access temporal blocks 30b and 30e in that same may not depend on any temporal block preceding the leading one among the random access temporal blocks 30b and 30e, here block 30b. Accordingly, leading temporal borders of the random access temporal blocks 30b and 30e are indicated by bold lines in FIG. 1.

Further, it might be that the coding of the coded channels also interrupts or restricts inter-channel dependencies by coding one or more of the coded channels as random access coded channels so that coding dependencies of these random access coded channels, or even these random access coded channels and the intermediate coded channels therebetween, are restricted so as to not reach-out beyond such a random access coded channel toward any coded channel preceding that random access coded channel in channel order along axis 32. Two such random access coded channels 88a and 88b and their associated inter-channel dependency borders are illustrated in FIG. 1.

The block predictor 62 and 86 of encoder 10 and decoder 12, respectively, operate synchronously, i.e., they generate the same prediction signal 64 based on the previously encoded/decoded samples of previously encoded/decoded temporal blocks 140. On encoder side 10, the prediction for a certain temporal block 140 may be accompanied or determined by one or more prediction parameters. Same might be determined on encoder side based on a rate/distortion optimization. These prediction parameters 90 are coded into data stream 16 and they are decoded from data stream 16 and used by block predictor 86 so as to perform the same prediction.

It might be that encoder 10 and decoder 12 support more than one prediction mode. For instance, encoder 10 and decoder 12 may support an intra prediction mode (which mode may also be called block-copy mode) according to which the currently encoded/decoded temporal block 140 is predicted based on the reconstructable sample values of previously encoded/decoded temporal blocks of the same coded channel to which the currently encoded/decoded temporal block 140 belongs, which is coded channel 92 in the example of FIG. 1. Additionally or alternatively, encoder 10 and decoder 12 may support an inter-prediction mode (which mode may also be called cross-channel prediction mode) according to which the currently encoded/decoded temporal block 140 is predicted based on the reconstructable sample values of previously encoded/decoded temporal blocks of coded channels preceding—in coding order 32—the coded channel 92 to which the currently encoded/decoded temporal block 140 belongs. Additionally or alternatively, there may be a mixed prediction mode according to which the prediction signal 64 is obtained by both, reconstructed/reconstructable sample values of previously encoded/decoded temporal blocks of coded channel 92 itself as well as reconstructed/reconstructable sample values of coded channels preceding coded channel 92 in channel order along axis 32. Beyond this, there may be temporal blocks 140 which are coded without any prediction at encoder 10 and decoded without any prediction at decoder 12 such as the first temporal blocks in the tiles 94 resulting from mutually separating the temporal blocks by means of the random access borders 96 on the one hand and the random access channel borders 98 on the other hand. This corresponds to the prediction signal 64 being set to zero and this may form an additional mode which could be called bypass mode. Additionally, or alternatively, there may be other modes such as ones deriving a DC predictor or linear function predictor for block 64 based on immediately preceding samples of block 140. The prediction parameters 90 may, thus, contain for a currently encoded/decoded temporal block 140 a prediction mode flag or prediction mode indicator indicating the prediction mode to be used for this currently encoded/decoded temporal block 140 and, optionally, one or more parameters parameterizing the prediction mode to be used for this currently encoded/decoded temporal block 140.

The aforementioned coding dependencies ought not to cross any of the borders 96 and 98 not only result from the just-described sample prediction capabilities of block predictor 62 and 86, respectively, but may optionally also result from other mechanisms such as parameter prediction according to which parameters such as the aforementioned prediction parameters 90 for a certain temporal block 140 are predicted based on coding parameters conveyed in the data stream 16 for any previous temporal block, or context derivation for context-adaptive entropy coding/decoding any coding parameter such as the prediction parameters 90 or any other side information such as side information 76 and 36 for temporal block 140 based on any coding parameter conveyed in the data stream 16 for any preceding temporal block.

That is, summarizing, the encoder 10 encodes the multi-channel signal 14 by transferring it into the coded domain 28 and then coding the coded channels into data stream 16 in the just-described block-wise and predictive manner, wherein decoder 12 decodes the coded channels of coded domain 28 from data stream 16 and the corresponding block-wise and predictive manner with then gaining the multi-channel signal 14 in its original form 26 based on the coded channels in coded domain 28 by means of segment 38. As said, the channel transformation is optional and if not used, each sample 40 in the coded domain 28 really corresponds to one sample 18 in the original domain 26. If, further, the temporal mutual alignment is not used, each sample 40 exactly corresponds to a sample 18 in the original domain 26 at exactly the same time instant or, differently speaking, all temporally co-located samples 40 in coded domain 28 remain mutually temporally co-located in the original domain 26.

As mentioned before, FIG. 1 only represents a possible “framework” into which the previously described embodiments and the embodiments described subsequently may be built into. Many modifications may be performed with respect to FIG. 1, and some of these modifications might be mentioned in the subsequent description with respect to certain ones of the subsequently described embodiments, but these modifications shall then be treated as being also applicable with respect to other ones of the subsequently described embodiments. Further, as a final note, and without being treated as forming an exclusive list of further possible amendments of the description of FIG. 1, it shall be noted that the temporal blocks 30 might, other than illustrated in FIG. 1, vary in block length rather than being of a constant length as depicted in FIG. 1. For instance, encoder 10 may decide on the length of blocks 30 and signal the block length of blocks 30 (and the corresponding temporal blocks 140 of the coded channels) within data stream 16. Further, although not described before, it might be that residual coder and residual decoder 70 and 82 may use transform coding/decoding in order to convey the residual signal 76 in data stream 16. That is, the residual signal 80 may be conveyed in data stream 16 in transform domain by way of transform coefficients in residual signal 76. The transform domain might be a DCT, DST or an FFT. The transform may be non-overlapping, i.e. it may only transform residual signal 80 and its re-transform may only cover residual signal 76 within block 140, and/or may be non-windowed, i.e. the residual signal might be transformed without any transform window used to temporally shape the residual signal 80 before the transform. The transform domain, i.e. the transformation leading from time domain to transform domain which is used by the encoder to transform the prediction residual signal 80 to be coded und the corresponding re-transformation leading from transform domain to time domain which is used by the decoder to derive the prediction residual signal 80, or the transformation, might be selected from a set of available transforms including, for instance, one or more of 1) one or more DCTs, 2) one or more DSTs and 3) an identity transform according to which the prediction residual signal 80 is coded into the data stream 14 in time domain directly. Some deblocking processing might be used to avoid blocking artifacts. If, alternatively, an overlapped transform is used, an overlap-add processing with re-transforms of immediately preceding/succeeding temporal blocks of the same coded channel might be used in order to completely reconstruct the current temporal block's 140 residual signal 76. Besides such transform-(residual)-coded blocks there might be temporal blocks 140 which, additionally or alternatively, are coded using, besides the block prediction by block predictor 62/86—which could be called a primary prediction—a secondary sample-wise prediction of the residual samples in residual block 66 such as by predicting a current sample's residual sample by means of already decoded values of preceding—in sample coding order—residual samples in block 66 or 80, with then correcting same by means of a secondary-prediction-residual sample decoded from the data stream 16. The secondary-prediction-residual samples for such a block may coded into the data stream on block in a transform domain or sample-wise in time domain.

The description is now resumed with respect to the announced subsequently described embodiments, here namely embodiments relating to inter-channel prediction. As described with respect to FIG. 1, the embodiments with respect to decoder and encoder described in the following may relate to such decoders and encoders which comprise the inter-channel prediction as one mode among one or more others, but the inter-channel prediction mode may alternatively be the only available prediction mode. That is, generally, FIG. 2 relates to a decoder for decoding a multi-channel digital signal 14 from a data stream 16, which is configured to decode coded channels representing the multi-channel digital signal 14, namely those in domain 28, from the data stream 16 in temporal blocks 140, namely temporal coded channel blocks, with sequentially decoding from the data stream 16 a predetermined temporal block 140 of each of the coded channels before decoding a subsequent temporal block of any of the coded channels, and to an encoder for encoding a multi-channel digital signal 14 into a data stream 16, which is configured to encode coded channels representing the multi-channel digital signal 14, namely those in domain 28, into the data stream 16 in temporal blocks 140, namely temporal coded channel blocks, with sequentially decoding from the data stream 16 a predetermined temporal block 140 of each of the coded channels before decoding a subsequent temporal block of any of the coded channels.

In order to describe the inter-channel prediction mode, reference is made to FIG. 2. In encoding/decoding a currently encoded/decoded temporal block 140, one or more prediction parameters for predicting the current temporal block 140 are determined first. The one or more prediction parameters are for, or control, the prediction of the current temporal block 140 of a predetermined coded channel 92 based on a reference block portion 142 of a set of one or more reference channels 92a. In FIG. 2, merely one such reference channel 92a is illustrated to be used for the prediction of temporal block 140 for illustration purposes and ease of explanation, but the number may be larger than one. As became clear from the description above, reference channels such as reference channel 92a need to precede the predetermined coded channel 92 in channel coding order 32 and might have, for instance, a lower channel index associated therewith than compared to predetermined coded channel 92 comprising the currently encoded/decoded temporal block 140. A further note shall be made with respect to the term “reference block portion”. Reference block portions such as reference block portion 142 are portions of immediately consecutive samples 40 of the reference channel 92a, with a number of comprised immediately consecutive samples 40 being equal to the number of samples within temporal block 140, but they are not necessarily restricted to be registered or to be temporally located to temporal block 140 or to any other temporal block 30, i.e. they might be placed freely expect for the fact that reference block portions need to comprise or cover previously decoded/encoded samples only, and except for an optional maximum temporal distance to block 140. That is, the reference block portions such as reference block portion 142 might be temporally shifted relative to temporal block 140 as described in more detail below.

The one or more prediction parameters determined for temporal block 140 are for defining as to how, computationally, the prediction signal 64 for predicting temporal block 140 is derived from the reference block portion(s) 142 or to be more precise, the reconstructed/reconstructable samples in reference block portion(s) 142. As will be described in more detail below, the one or more prediction parameters may, for instance, define scale and offset such as a scale for each reference block portion 142 by means of which the reference block portion 142 is scaled (by multiplying it or, to be more precise, its reconstructed/reconstructable samples, by multiplication with the scale), with then adding the offset to the scaled reference block portion or, in case of more than one reference block portion 142, forming a sum over all scaled reference block portions and the offset.

The determination of the one or more prediction parameters is done based on temporal segments 144 and 146 of channels 92 and 92a, each consisting of immediately consecutive samples 40 of the respective channel, and each of which temporally preceding the corresponding block, i.e. block 140 in coded channel 92, and reference block portion 142 in channel 92a, respectively. For instance, segments 144 and 146 might be defined to be located immediately preceding the corresponding block 140 and 142, respectively, as illustrated in FIG. 2, but it might alternatively be that the temporal positioning of segments 144 and 146 is defined in a different manner such as in a manner so that the segments 144 and 146 are mutually temporally co-located such that, for instance, all segments 144 and 146 contain the samples 40 immediately preceding, temporally, the block among block 140 and block 142 which is the earliest in time. As can be seen in FIG. 2, segments 144 and 146 mutually coincide in the number of samples 40 contained therein, wherein this number L may be equal to or different from the number N of samples in blocks 140 and 142, respectively. For instance, L might be chosen to be smaller than N as illustrated in FIG. 2. The advantage of determining the one or more prediction parameters using which temporal block 140 is predicted from the reference block portion 142 of the one or more reference channels 92a based on an evaluation of the temporal segments 144 and 146, is the fact that this determination may be done by both encoder 10 and decoder 12 because the temporal segments 144 and 146 are both comprised by the reservoir or pool of already encoded/decoded samples so that the determination of the one or more prediction parameters may be done inherently without any explicit signaling in data stream 16, thereby reducing the side information signaling overhead.

The determination itself is done in the following manner: in particular, it is a pretty good assumption that a relationship of the currently encoded/decoded temporal block 140 to the reference block portion 142 of the one or more reference channels 92a is the same as, or is at least pretty close to, the relationship of temporal segment 144 of coded channel 92 relative to the temporal reference segment 146 in each reference channel 92a. Thus, if the one or more prediction parameters are determined so that their application onto the temporal reference segment 146 of the one or more reference channels 92a results into a “prediction” for temporal segment 144 which minimizes the prediction residual towards the temporal segment 144, this one or more prediction parameter should, if the assumption holds true, also minimize the deviation of the prediction signal 64 obtained by applying the one or more prediction parameters thus determined onto the reference block portion 142 of the one or more reference channels 92a from the block 140 to be coded/decoded. As a result, the prediction residual 80 coded into data stream 16 may be coded with fewer bits due to the preciseness in having derived prediction signal 64.

If the one or more prediction parameters consist of a scale for the, in case of only one reference block portion, reference block portion 142 or for each reference block portion 142 in case of having more than one reference block portion, and an offset, as just-described, then the determination of this scale and offset may be performed as follows with here assuming that x₁, . . . , x_{N} denote the reconstructed/reconstructable samples in segment 144, while y_{i,j} denotes the j^{th} sample in segment 146 of the i^{th} reference block portion with i∈{1, . . . , K}, and j∈{1, . . . , L} and λᵢ denoting the scale for the i^{th} reference block portion and b denoting the offset. Then, the minimization of the deviation when applying the prediction parameters onto y_{i,j} from samples xⱼ in terms of sum of squares, i.e.

$${\sum }_{j = 1}^{L} {( {x}_{j} - {\sum }_{i = 1}^{K} ( {λ}_{i} \cdot {y}_{i , j} - b ) )}^{2} \to min$$

is achieved by the solution of the following equation and, thus, decoder and encoder solve this linear equation and in doing so, decoder and encoder may use a lookup table in order to avoid the computation of the scale and offset involving a division. The equation is:

$$M \cdot ( \begin{matrix}{λ}_{1} \\ ⋮ \\ {λ}_{K} \\ 1\end{matrix} ) = ω$$

$$with$$

$$M = {( {M}_{k , l} )}_{k , l = 1}^{K + 1} ∈ {ℝ}^{( K + 1 ) \times ( K + 1 )}$$

$${M}_{k , l} = \{ \begin{matrix}{\sum }_{j = 1}^{L} ( {y}_{k , j} \cdot {y}_{l , j} ) , & if k , l \leq K \\ {\sum }_{j = 1}^{L} {y}_{k , j} , & if l = K + 1 and k \leq K \\ {\sum }_{j = 1}^{L} {y}_{l , j} , & if k = K + 1 and l \leq K \\ L , & if k = l = K + 1\end{matrix}$$

$$ω = ( {ω}_{1} , … , {ω}_{K + 1} ) ∈ {ℝ}^{K + 1}$$

$${ω}_{i} = \{ \begin{matrix}{\sum }_{j = 1}^{L} {x}_{j} \cdot {y}_{i , j} , & if i \leq K \\ {\sum }_{j = 1}^{L} {x}_{j} , & if i = K + 1\end{matrix}$$

Thus, as described, the inter-prediction according to FIG. 2 may involve one or more reference block portions 142 and the computation of the one or more prediction parameters may be performed in a manner avoiding a division which is approximated by way of a table lookup instead.

It is further noted that, in case of more than one reference block portion 142 being used for the currently encoded/decoded temporal block 140, each one of same is, according to an embodiment, contained in a separate one of the reference channels. That is, each reference channel would have exactly one reference block portion. However, as an alternative, it might be that the reference block portions partially, or all of same, belong to a common reference channel such as reference channel 92a.

As already mentioned above, the reference block portion(s) 142 might be located temporally offset relative to temporal block 140. For instance, datastream 16 may have, for each of a set of one or more inter-channel predicted channels out of the coded channels, for each of the one or more reference channels, a temporal offset 148 encoded thereinto at which 1) the reference block portion 142 of the respective reference channel 92a is temporally offset, such as delayed as depicted in FIG. 2, relative to the current temporal block 140 of the predetermined coded channel, and 2) the preceding temporal reference block portion 146 of the respective reference channel 92a is temporally offset, such as delayed as depicted in FIG. 2, relative to the preceding temporal block portion 144 of the predetermined coded channel 92. The decoder 12 decodes the temporal offset 48 from the datastream 16 accordingly. The granularity at which this temporal offset 48 is coded in the data stream 16 may be designed in one of the following options: for instance, the temporal offset 48 for each reference channel for a certain inter-channel predicted coded channel might be coded into datastream 16 at a scope valid for the whole datastream, or may be coded for each sequence of temporal blocks 30 from a random access temporal block such as 30b until the temporal block 30d immediately preceding the next random access temporal block 30e, or may be conveyed in datastream 16 temporal block individually, i.e. for each inter-predicted temporal block such as segment 140, individually. The set of one or more inter-channel predicted coded channels may include all channels except for the random access coded channels 88a and 88b (wherein in FIG. 1 the coded channel corresponding to the uppermost sample line might also be a random access coded channel, as it might be the first channel in channel order 32). The number of reference channels might also be coded in the datastream 16 in any of the just-mentioned granularities and even at a granularity which differs from the granularity at which the temporal offset signaling is done. The number of reference channels might be chosen to be equal for all inter-channel predicted coded channels, or might be signaled in the datastream 16 in a manner so that the number of reference channels differs among the inter-channel predicted channels. In case of allowing two reference block portions to belong to the same reference channel, for each reference channel, it might additionally be signaled as to how many reference block portions are contained in the respective reference channel for a certain inter-channel predicted coded channel. In any case, the decoder uses the temporal offset 48 coded in the datastream in order to cut-out out of the respective reference channel, or derive, the reference block portion 142 and the preceding temporal reference block portion 146 from the respective reference channel 92a using the temporal offset 148 signaled for the respective reference channel. Further, the datastream 16 may have, for each of the set of one or more reference channels, a channel index coded thereinto, which identifies the respective reference channels out of the coded channels which precede the coded channel 92 in channel order 32. Alternatively, the set of one more reference channels of a certain inter-channel predicted coded channel might, by default, include all those coded channels preceding in channel order 32, which immediately precede the current channels 92 in channel order. As described before, for each inter-channel predicted coded channel, the number of coded channels which may form one of the set of one or more reference channels, is restricted as same are merely allowed to be recruited from the coded channels preceding the respective inter-channel predicted coded channel up to the nearest preceding random access channel such as channel 88a in case of channel 92 in FIG. 1. Accordingly, a channel index conveyed in the datastream 16 may be coded into datastream 16, and may be decoded therefrom, using a parametrized binarization, such as a truncated unary code, parametrized using a binarization parameter, such as the truncation parameter, which might be set by encoder and decoder in such a manner so that the number of binary strings formed by the parametrized binarization becomes closest to—with becoming equal or greater than—this number of coded channels preceding the respective inter-channel predicted coded channel in channel order 32 up to the nearest—in channel order—preceding random access channel. With respect to the temporal offset 148 and the derivation of the temporal reference block portion 46 and the reference block portion 142 from the reference channel 92a, the following is noted. In particular, according to an embodiment, the temporal offset 148 is restricted to full-sample offsets, meaning that the temporal reference block portion 146 as well as the reference block portion are respectively formed by consecutive samples 40 of the corresponding reference channel, the consecutive samples being shifted relative to the samples of block portion 144 and segment 140, respectively, by a number of samples indicated by offset 148. The derivation of reference block portion 146 and reference block portion 142 is, thus, merely a cutting-out of the corresponding samples out of the samples of reference channel 92a. However, alternatively, the temporal offset 148 may also allow for sub-sample offsets so that the derivation might include a sub-sampling of the reference channel to result into reference block portion 146 and reference block portion 142, respectively.

A further note shall be made with respect to the freedom for encoder 10 to choose the temporal offset 148, the number of reference channels and the selection of the number of reference channels out of the available preceding coded channels for a certain coded channel 92, or for a subset of these settings. For instance, the encoder 10 may determine these parameters or settings as optimization variables in a rate/distortion optimization scheme, or may select same in a different manner such as by inspecting certain similarity measures or the like.

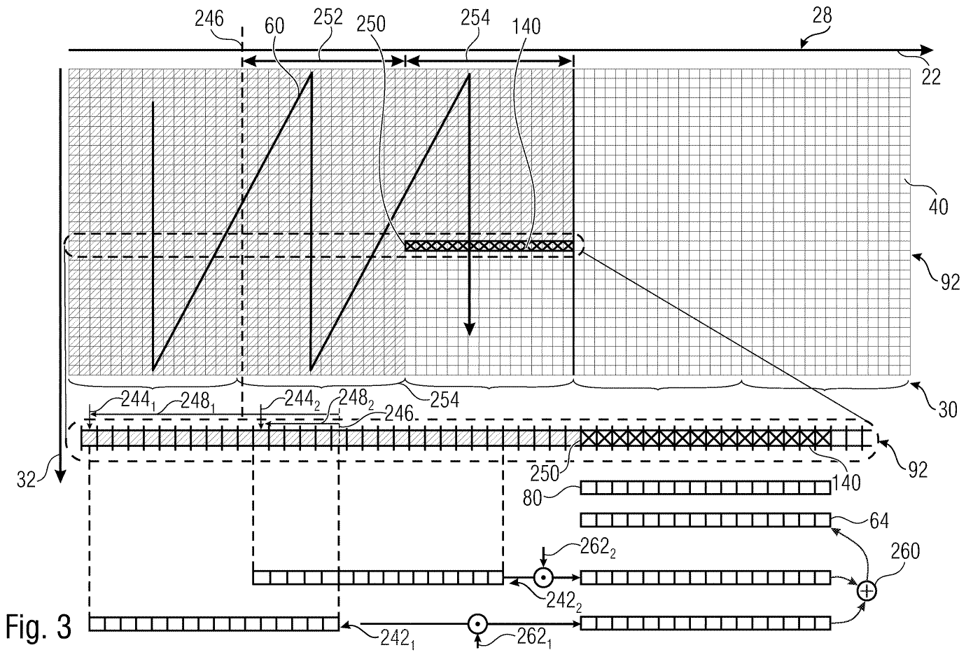

In the following, the announced subsequent embodiments dealing with intra prediction are presented. As outlined above, these details describe an encoder and a decoder for encoding/decoding a multi-channel digital signal 14, wherein these embodiments may be combined with a teaching of a possible framework presented above with respect to FIG. 1, both with adopting all details presented with respect to FIG. 1 as well as combining subsequent embodiments merely with a subset of these details. Generally, FIG. 3 presents embodiments for a decoder configured to decode coded channels representing a multi-channel digital signal 14 from the data stream 16 in temporal blocks 140, and an encoder configured to encoder coded channels representing a multi-channel digital signal 14 into the data stream 16 in temporal blocks 140.

According to FIG. 3, a current temporal block 140 of a predetermined coded channel is predicted from one or more reference block portions 242₁ and 242₂ of the same channel, i.e. the predetermined coded channel 92. The “reference block portions” equal the currently encoded/decoded temporal block 140 in the number of samples, but same are not restricted to be registered to any of the temporal blocks 30 and beyond this, in accordance with the embodiments described herein below, they might be positioned at, and be derived from, sub-sample positions of channel 92.

In FIG. 3, the number of reference block portions is two but this number may also be one or be larger than two. In particular, the number of reference block portions might be determined by the encoder 10 and signaled in the datastream. The number might be determined for each intra-predicted temporal block 140 individually and signaled in the datastream for that segment 140 individually. Alternatively, the number is signaled in the datastream 16 at a coarser time/channel grid. For instance, the number might be signaled in the datastream channel-globally, i.e. for all coded channels, with being updated intermittently such as for each temporal block 30 or for each sequence of temporal blocks 30 from a random access temporal block such as segment 30b up to the temporal block 30d immediately preceding the next random access temporal block 30e. Even alternatively, the number of reference block portions might be signaled in the datastream 16 channel-individually but for a period comprising more than just one temporal block 140 of that channel such as channel 92.

The datastream 16 might have, for each of the one or more reference block portions 242₁ and 242₂, a position 244₁, 244₂ of the respective reference block portion coded thereinto. In particular, this position might be the starting position of the respective reference block portion as depicted in FIG. 3. As the starting position needs to be distanced from the beginning 250 of the intra-predicted temporal block 140 by at least a temporal distance 252 equaling the temporal length 254 of temporal block 140 itself, the starting position 144_{1/2} might be coded into the datastream as a temporal offset 248₁ and 248₂ relative to a temporal reference position 246 lying at the temporal distance 252 ahead beginning 250.

The position may be coded into the datastream 16 at sample accuracy or at sub-sample accuracy. According to an embodiment, it is signaled in the datastream whether the position is coded into the datastream at sample accuracy or sub-sample accuracy and, in case of more than one sub-sample accuracy being available, at which sub-sample accuracy. The signaling of this accuracy may, again, be done individually for the intra-predicted temporal block 140, or be done at a coarser temporal and/or channel grid. For instance, the accuracy may be signaled channel-globally, i.e. for all coded channels commonly, and in temporal terms, it may be signaled in the datastream for the whole datastream or for each sequence of temporal blocks 30 from a random access temporal block onwards up to the temporal block immediately preceding the next random access temporal block, or for each temporal block 30. Even alternatively, the accuracy may be signaled channel-individually but for periods encompassing more than just one temporal block 140.

If the position of a predetermined reference block portion 242_{1/2} falls onto a sub-sample position, the predetermined reference block portion 242_{1/2} is derived from channel 92 by sampling this channel 92 using an interpolation filter at a grid of sub-sample positions which grid has a temporal length of temporal block 142, i.e. has the same number of samples, and is placed at the sub-sample position 244_{1/2}.

If the number of reference block portions 142_{1/2} is larger than one, as it is the case in FIG. 3, the prediction signal 64 of temporal block 140 may be derived based on a sum 260 of the reference block portions 242₁ and 242₂. The sum may be a weighted sum so that reference block portion 242₁ is weighted using a factor 262₁ before being subject to addition 260, while reference block portion 242₂ might be weighted by a factor 262₂ before being subject to addition 260. Again, the same statements on granularity of signalization as done above with respect to the position signaling holds true with respect to a signalization of one, a subset of, or all of the weights/factors 262_{1/2} in datastream 16, wherein the granularity may be equal to the one of the signalization of the position or different thereto. However, the weights might be set be default and, optionally, they might be equal to each other, such as the inverse of the number of reference block partitions.

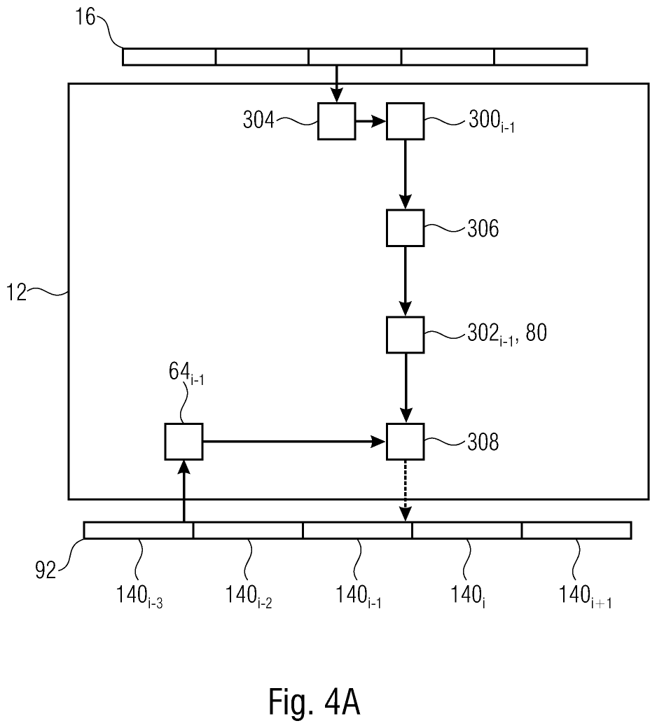

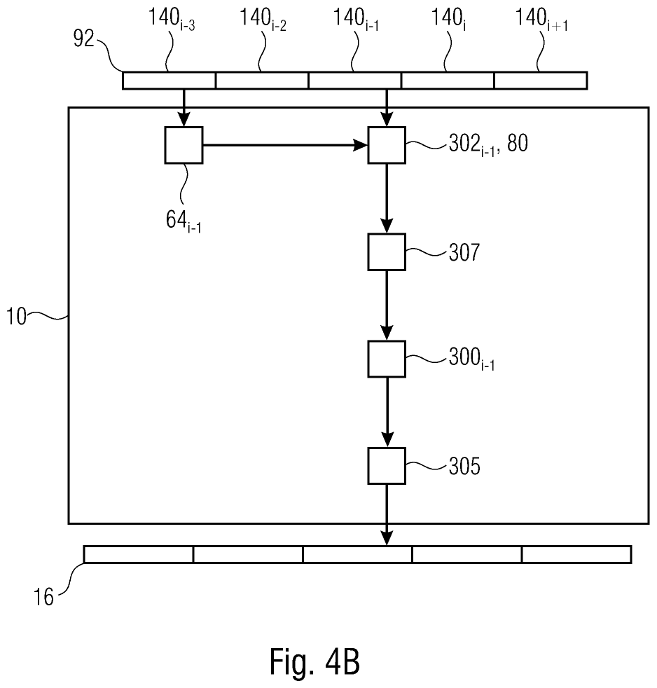

FIG. 4A shows a schematic view of a decoder 12 for decoding a digital time-varying signal 92 from a data stream 16. The decoder 12 may be any decoder described herein. Furthermore, the decoder 12 may comprise any feature (e.g., in isolation or in combination with one or more other features) of any decoder disclosed herein.

The decoder 12 is configured to decode the digital time-varying signal 92 from the data stream 16 in non-overlapping temporal blocks 140 by decoding each of transform-coded temporal blocks 140ᵢ₋₁ of the non-overlapping temporal blocks 140 of the digital time-varying signal 92 by predicting the respective transform-coded temporal block 140ᵢ₋₁ using a selected prediction mode out of a set of prediction modes to obtain a prediction signal 64ᵢ₋₁ (e.g., in FIG. 4A exemplarily derived from temporal block 140ᵢ₋₃), decoding 304 coefficients 300ᵢ₋₁ from the data stream 16, the coefficients representing a prediction residual signal 80 of the respective transform-coded temporal block 140 in a transform domain, subjecting 306 the coefficients 300ᵢ₋₁ to a predetermined re-transformation from the transform domain to a time domain to obtain a time-domain prediction residual signal 302ᵢ₋₁ representing a prediction residual signal 80 of the respective transform-coded temporal block 140 in a time domain, and correcting 308 the prediction signal 64ᵢ₋₁ using the time-domain prediction residual signal (302ᵢ₋₁), wherein the predetermined re-transformation is a non-overlapping transform. The corrected prediction signal 64ᵢ₋₁ may form the temporal block 140ᵢ₋₁ or may optionally be further processed (e.g., subjected to further prediction and/or filtering).

FIG. 4B shows a schematic view of an encoder 10 for encoding a digital time-varying signal 92 into a data stream 16. The encoder 10 is configured to encode the digital time-varying signal 92 into the data stream 16 in non-overlapping temporal blocks 140 by encoding each of transform-coded temporal blocks 140ᵢ₋₁ of the non-overlapping temporal blocks 140 of the digital time-varying signal 92 by predicting the respective transform-coded temporal block 140ᵢ₋₁ using a selected prediction mode out of a set of prediction modes to obtain a prediction signal 64ᵢ₋₁, subjecting 307 a time-domain prediction residual signal 302ᵢ₋₁ representing a prediction residual signal 80 of the respective transform-coded temporal block 140ᵢ in a time domain to a predetermined transformation from the time domain to a transform domain to obtain coefficients 300ᵢ₋₁ representing the prediction residual signal 80 of the respective transform-coded temporal block 140ᵢ₋₁ in the transform domain, and encoding 305 the coefficients 300ᵢ₋₁ into the data stream 16 so as to be used for correcting 308 the prediction signal 64ᵢ₋₁, wherein the predetermined transformation is a non-overlapping transform. The encoder 10 may optionally be configured to correct the prediction signal 64ᵢ₋₁ using the time-domain prediction residual signal in order to obtain a corrected prediction signal 64ᵢ₋₁. The encoder 10 be configured to (e.g., temporally) store the corrected prediction signal 64ᵢ₋₁ (e.g., as potential reference for future predictions).

The encoder 10 may be any encoder described herein. Furthermore, the encoder 10 may comprise any feature (e.g., in isolation or in combination with one or more other features) of any encoder disclosed herein.

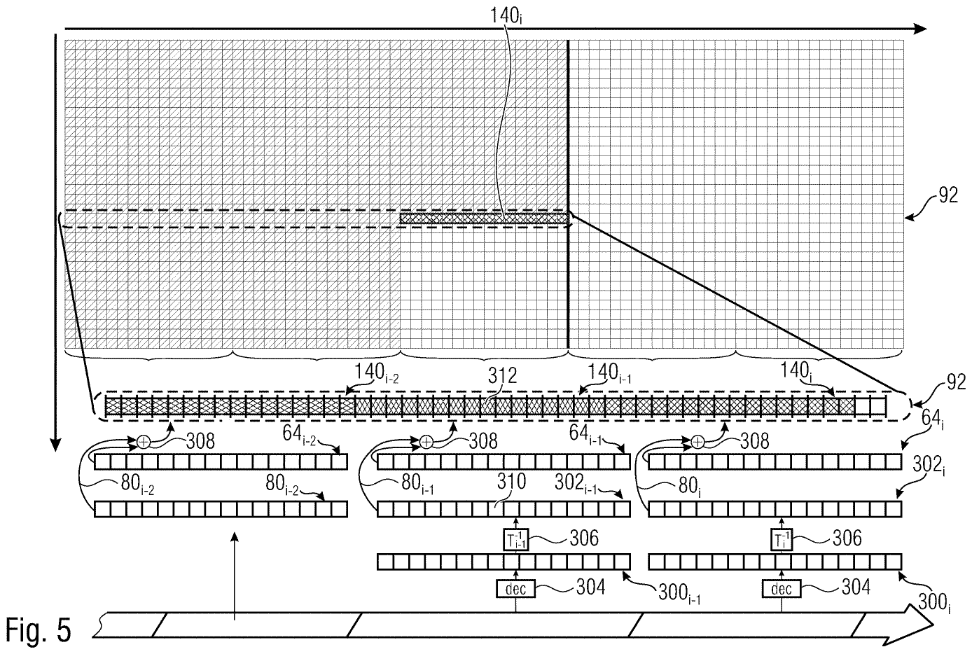

FIG. 5 shows a schematic view of decoding a digital time-varying signal 92 from a data stream 16. The decoding (or in general, a method thereof) may be performed by any decoder 12 disclosed herein.

The decoder 12 is configured to decode the digital time-varying signal 92 from the data stream 16 in non-overlapping temporal blocks 140 by decoding each of transform-coded temporal blocks 140ᵢ₋₁ of the non-overlapping temporal blocks 140 of the digital time-varying signal 92 by predicting the respective transform-coded temporal block 140ᵢ₋₁ using a selected prediction mode out of a set of prediction modes to obtain a prediction signal 64ᵢ₋₁, decoding 304 coefficients 300ᵢ₋₁ from the data stream 16, the coefficients representing a prediction residual signal 80 of the respective transform-coded temporal block 140 in a transform domain (e.g., frequency domain), subjecting 306 the coefficients 300ᵢ₋₁ to a predetermined re-transformation from the transform domain to time domain to obtain a time-domain prediction residual signal 302ᵢ₋₁ representing a prediction residual signal 80 of the respective transform-coded temporal block 140 in a time domain, and correcting 308 the prediction signal 64ᵢ₋₁ using the time-domain prediction residual signal 302ᵢ₋₁, wherein the predetermined re-transformation is a non-overlapping transform.

The digital time-varying signal 92 may comprise one or more channels. Alternatively, the digital time-varying signal 92 may be part of (e.g., in form of one or more channels) of an overall digital time-varying signal. A channel may define a single parameter assuming values over time, e.g., wherein the parameter is sampled over temporally successive samples. The time digital time-varying signal 92 may comprise or be an audio signal (e.g., having one or more audio channels), a biomedical signal (e.g., an electrogram such as obtained by electroencephalography, electrocardiogram, or electrooculography), or a seismic signal. Any decoder 12 disclosed herein may be a decoder 12 for decoding an audiosignal, a biomedical signal, or a seismic signal. Any encoder 10 disclosed herein be an encoder for encoding an audiosignal, a biomedical signal, or a seismic signal. The digital time-varying signal 92 may be or comprise one or more waveform signals. Any disclosure related herein to examples with a single channel may also be applicable in any combination to digital time-varying signal 92 having multiple channels.

Two temporal blocks 140 may be considered non-overlapping, if they do not comprise a common sample (e.g., a last sample of a first temporal block is also a first sample of a second temporal block). Furthermore, two non-overlapping temporal blocks 140 may adjoin each other immediately, e.g., along a temporal axis (e.g., wherein a last sample of a first temporal block immediately precedes a last sample of a second temporal block).

The predetermined re-transformation may be configured to output a set of a samples, wherein the set of samples has a number of samples that is equal to (or at least not larger than) a number of samples of currently decoded temporal block 140 (or all temporal blocks, e.g., in case all temporal blocks 140 have the same size or number of samples, e.g., within a temporal block 30 or the entire digital time-varying signal 92. The predetermined re-transformation may be configured to output such a set of a samples when the transform-coded temporal block 140ᵢ₋₁ is subjected to the predetermined re-transformation, e.g., for a predetermined number (or range of numbers) of coefficients 300ᵢ₋₁ in the transform-coded temporal block 140ᵢ, independent of a number of coefficients 300ᵢ₋₁ in the transform-coded temporal block 140ᵢ₋₁. The predetermined re-transformation may comprise an algorithm that prevents the number of output samples to exceed the number of samples of the temporal block 140 and/or a cropping step for cropping samples that exceed the number of samples of the temporal block 140.

Correcting the prediction sample value 64ᵢ₋₁ using the residual sample value 80 may comprise (or be realized by) a linear combination (e.g., a sum or a weighted sum, e.g., sample-wise) of the prediction sample value 64ᵢ₋₁ and the time-domain prediction residual signal 302ᵢ₋₁.

It is noted that in the example shown in FIG. 5, the currently coded temporal block has an index of i−1, which is partly for illustrating an optional relationship with a subsequently coded temporal block 300ᵢ described further below. However, the same teachings may apply to any other index or generally any temporal block 140 within the digital time-varying signal 92. Furthermore, the decoder 12 may be configured to perform the decoding method described herein for one, more than one or all temporal blocks 140 of digital time-varying signal 92 or a subset thereof (e.g., of a temporal block 30). For example, the decoder 12 may be configured to perform the decoding method described herein for every temporal block 140 (e.g., of the digital time-varying signal 92 or a subset thereof), except for temporal blocks 140 that are decoded in a random access manner (e.g., decoded without prediction using or referencing samples outside the temporal block to be decoded). Alternatively or additionally, the decoder 12 may be configured to perform the decoding according to the method disclosed herein depending on a signalling (e.g., a flag), which indicates whether to perform said decoding.

The predetermined re-transformation (e.g. Tᵢ₋₁⁻¹, see reference sign 306 in FIG. 5) may be (or comprises) an inverse discrete cosine transform or an inverse discrete sine transform.

The predetermined re-transformation may be representable by a matrix multiplication between a transform matrix and a first vector whose components are formed by the coefficients 300ᵢ₋₁ (e.g., wherein the first vector has a length corresponding to a number of coefficients 300₋₁), wherein an output vector resulting from the matrix multiplication has as many components as samples 310 comprised by the time-domain prediction residual signal 302ᵢ₋₁. For example, the transform matrix may comprise a number of rows that is equal to (or smaller) than a number of samples of the temporal block 140 to be decoded. The transform matrix may comprise a number of columns that is equal to a number of coefficients 300ᵢ₋₁ of the transform-coded temporal block 140ᵢ₋₁. The different transform matrix may be provided, for example, for DCT or DST. The matrix may optionally depend on block length and/or quantization step size.

The transform domain may result from the time domain according to a predetermined transformation (e.g., Tᵢ₋₁, e.g., performed by the encoder 10), wherein the decoder 12 may be configured to select the predetermined transformation out of a set of transformations (e.g. to select the predetermined re-transformation out of a set of re-transformations, e.g., select the transformation matrix), wherein the re-transformation reverses the predetermined transformation (e.g., Tᵢ₋₁⁻¹Tᵢ₋₁=1).

The decoder 12 may be configured to select the set of transformations out of a superset of transformations (e.g. to select the set of re-transformations out of a superset of re-transformations, e.g., select a set transformation matrices out of a superset of transformation matrices) depending on one or more of a length of the respective transform-coded temporal block 140ᵢ₋₁, e.g., a number of total transform coefficients 300ᵢ₋₁, e.g., a number of total non-zero transform coefficients 300ᵢ₋₁), a length of the time domain temporal block 140 (e.g., N, e.g., number of samples of the temporal block), and the selected prediction mode for the respective transform-coded temporal block 140ᵢ₋₁ (e.g., a DC prediction mode, a linear prediction mode, or any other prediction mode disclosed herein).

The set of transformations comprises one or more of one or more discrete cosine transforms, one or more discrete sine transforms, and an identity transform. For example, the set of transformations may comprise a first matrix that realizes a discrete cosine transforms, a second matrix that realizes a discrete sine transform, and a third matrix that realizes an identity transform (e.g., with a value of one on its diagonal, e.g., with values of zero at non-diagonal positions).

The decoder 12 may be configured to skip the subjecting 306 the coefficients to the predetermined re-transformation if the predetermined transformation is the identity transform. For example, transform coefficients 300ᵢ₋₁ may be used by as samples of the temporal block 140ᵢ₋₁, e.g., with optional padding with zeroes.

The transform domain may result from the time domain according to a predetermined transformation (e.g., performed on the encoder side), wherein the predetermined transformation and the predetermined re-transformation are windowing free. For example, predetermined transformation and the predetermined re-transformation may not employ a window that extends beyond the samples of the temporal block 140ᵢ₋₁ or the transform coefficients 300ᵢ₋₁ of the transform-coded temporal block 140ᵢ₋₁. The predetermined transformation and the predetermined re-transformation may employ a rectangular window, that does not extend beyond the respective block and employs no weighting against each other (e.g., a constant weight of one for every sample or transform coefficient).

The transform domain may result from the time domain according to a predetermined transformation, wherein the predetermined transformation is a spectrally decomposing transformation. For example, the predetermined transformation may be or comprise one or more of a fourier transform, a discrete fourier transform, a fast fourier transform, a short-time fourier transform, a wavelet transform, and a discrete cosine (or sine) transform.

A sample rate of the digital time-varying signal 92 may be above, or equal to, a Nyquist rate of the transform domain.

For each transform-coded temporal block, a number of the coefficients 300ᵢ₋₁ may coincide with a number of samples 312 of the respective transform-coded temporal block. For example, if a transform-coded temporal block as eight coefficients 300ᵢ₋₁, the temporal block (e.g., in the time domain) may also have eight samples (e.g., or the number of coefficients may be equal to or smaller than the number of samples).

The time-domain prediction residual signal 302ᵢ₋₁ may result from the subjecting 306 the coefficients 300ᵢ₋₁ of the respective transform-coded temporal block 140ᵢ₋₁ to the predetermined re-transformation in a manner independent from a prediction residual signal 80 of temporally adjacent temporal blocks (140ᵢ, 140ᵢ₋₂), preceding and following the respective transform-coded temporal block (140ᵢ₋₁). For example, some overlapping methods employ a transformation of coefficients of the currently coded temporal block with some (e.g., half) of the prediction residual 80 of a previously coded (e.g., 140ᵢ₋₂). However, the decoder 12 may be configured to subject 306 exclusively the coefficients 300ᵢ₋₁ of the currently decoded transform-coded temporal block 140ᵢ₋₁ to the predetermined re-transformation.

Transform domain may be a critically sampled transform domain. For example, the transform domain may be sampled at a Nyquist rate, e.g., at twice a highest frequency of sample (e.g., within a temporal block or a more general set of samples such as temporal block 30).

Basis functions of the predetermined re-transformation may be of a length coinciding with a length of the respective transform-coded temporal block (140ᵢ₋₁). For example, basis functions may comprise a trigonometric function such as cosine or sine functions, wherein the length of the transform-coded temporal block may coincide with an integer multiple of half (or full) period of such a cosine or sine function (e.g., cos (π/N·i), with a length N of coefficients and an index i for cosine functions that may form a basis for the basis functions).

The set of prediction modes may comprise one or more of a DC prediction mode, one or more linear prediction modes, a block-copy prediction mode, a cross-channel prediction mode, and a bypass prediction mode.

According to the DC prediction mode, the prediction signal of the respective transform-coded temporal block may be determined to be (and/or, for example, determined by) a constant function with a determination of a constant of the constant function based on predetermined already decoded samples preceding the respective transform-coded temporal block. For example, the constant may be determined based on one or more of an average, sum, and weighted sum of the already decoded samples (and optionally a bias, e.g., for adapting to a rounding shift), e.g., immediately preceding samples, e.g., of K samples, wherein K is an integer number smaller than a number of already decoded samples (e.g., with K being pre-determined, e.g., with K being a power of two).

According to the one or more linear prediction modes, the prediction signal of the respective transform-coded temporal block may be determined to be (and/or, for example, determined by) a linear function with a determination of at least one of a slope and an offset of the linear function based on predetermined already decoded samples preceding the respective transform-coded temporal block. The offset may be determined based on one or more immediately preceding decoded samples, e.g., based on an average or weighted sum. The offset may be determined as or based on a sample immediately preceding the temporal block to be decoded. The slope may be determined based on an extrapolation of immediately preceding samples (e.g., two already decoded samples immediately preceding the temporal block to be decoded). The slope determined from two or more preceding samples may be further modified, for example, reduced (e.g., by a factor of two or four). The one or more linear prediction modes may include one or more of a half-slope prediction and a quarters-lope prediction.

According to the block-copy prediction mode, the prediction signal of the respective transform-coded temporal block may be predicted based on one or more reference block portions of already decoded samples preceding the respective transform-coded temporal block offset relative to the respective transform-coded temporal block at a position signalled for the respective transform-coded temporal block in the data stream. The block-copy prediction mode may be restricted to referencing only the same channel as the temporal block to be predicted (e.g., obtaining only one or more than one reference block portion). The block-copy prediction mode may reference (e.g., perform a prediction based on a referenced block portion, e.g., obtain a reference block portion) more than one channel, e.g., wherein each of the more than one channels may be reference once (or more than once). The block-copy prediction may reference all available channels (e.g., within a set of channels between two random access coded channels). In case of referencing a single reference block portion, samples of the block portion may be copied (or referenced) with a weight of one (e.g., and/or smaller than one). In case of referencing more than one reference block portion, the reference block portions may (e.g., sample-wise) be subjected to a weighted sum (e.g., with equal weights or non-equal weights, e.g., with signalled weights).

According to the cross-channel prediction mode, the prediction signal of the respective transform-coded temporal block may be predicted based on one or more reference coded channels out of coded channels which represent a multi-channel signal 14 coded into the data stream and to be decoded from the data stream by the decoder 12, and one of which is represented by the digital time-varying signal 92.

According to the bypass prediction mode, the prediction signal of the respective transform-coded temporal block is set to zero.

The decoder 12 may be configured to select a prediction mode out of a set of prediction modes, wherein the set of prediction modes depends on a size of (or length or amount of or samples in) the temporal block to be decoded. For example, a first set of prediction modes may be provided for a block size up to (or equal to) a size threshold and a second set of prediction modes may be provided for a block size larger than the size threshold. For example, a first set of prediction modes may include the one or more linear prediction modes (e.g., include a half-slope prediction and a quarters-lope prediction modes) and a second set of prediction modes may not include the one or more linear prediction modes (e.g., not include the half-slope prediction and a quarters-lope prediction modes), wherein, for example the first set of prediction modes may be provided (or used) for blocks with a block size smaller than and equal to 64 samples and the second set of prediction modes may be provided for blocks with a size greater than 64 samples.

The digital time-varying signal 92 may be obtained by at least one of Electrocardiography, Electroencephalography, Electromyography or seismic measurement, and/or wherein the digital time-varying signal 92 may be a bio-physiological waveform data such as an electroencephalography (EEG) signal, an electrocardiogram (ECG), or an electromyography (EMG) signal, or is a seismic waveform signal. The digital time-varying signal 92 may be (or comprise) a signal (e.g., electrogram) repetitive of (or based on a measurement of) electrophysiological activity, e.g., of a heart, brain, muscles, eyes, or cochlea. The digital time-varying signal 92 may be (or comprise) a signal (e.g., seismogram) repetitive of (or based on a measurement of) vibrations, shaking, or quaking of the ground.

The decoder 12 may be configured to support different lengths (e.g., number of transform coefficients 300, after which the transform coefficients 300 are only zero, e.g., a rank of a last non-zero coefficient of the transform-coded temporal block) of the transform-coded temporal blocks 140 and set a length of the transform-coded temporal blocks 140 according to a length parameter in the data stream 16. The length of the transform-coded temporal blocks 140 may be coded for every transform-coded temporal block 140, a set of transform-coded temporal blocks 140 (e.g., every temporal block 30) or at the start of the digital time-varying signal 92. The decoder 12 may be configured to assume a pre-determined length in case no length is signalled and/or to assume a first length (e.g., pre-determined or previously signalled) is to be used for temporal blocks 140 until a (new) second length is signalled.

The decoder 12 may be configured to support different lengths of the transform-coded temporal blocks and switch between the different lengths of the transform-coded temporal blocks at predetermined borders between consecutive temporal blocks according to a length parameter in the data stream. For example, predetermined borders may be arranged (e.g., signalled) between each temporal block or between sets of temporal blocks (e.g., after each temporal block 30, e.g., before a temporal block that is coded in a random access manner).

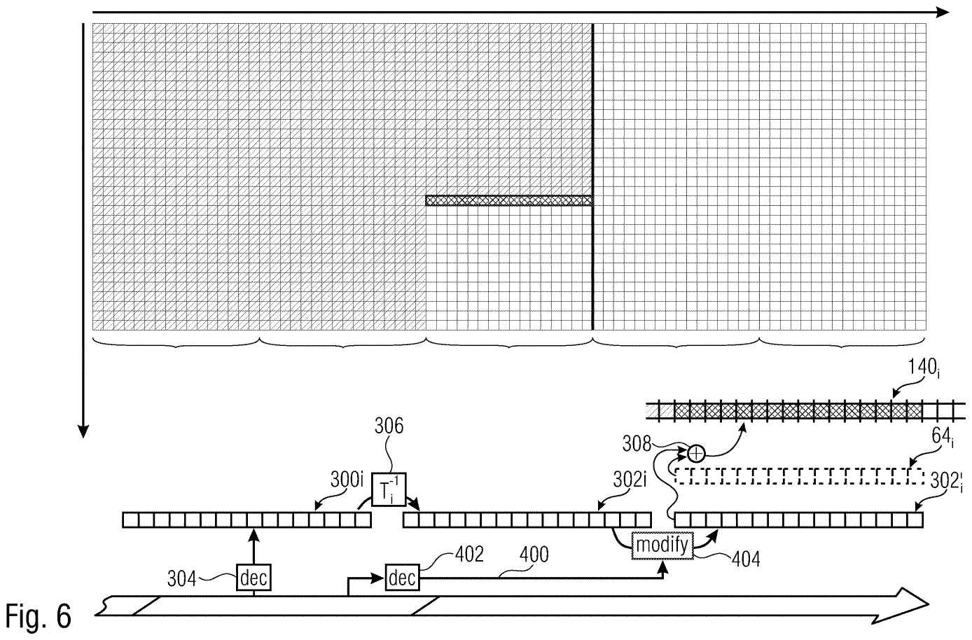

FIG. 6 shows a schematic coding scheme for decoding comprising modifying 404 the time-domain prediction residual signal 302ᵢ. Any decoder 12 disclosed herein may be configured to perform one or more features disclosed herein with reference to FIG. 6. The same features may be provided for a corresponding encoder 10 (e.g., any encoder disclosed herein). It is note that FIG. 6 uses an index i for the currently coded temporal block, for easier readability. However, the currently coded temporal block 300ᵢ in FIG. 6 may correspond to the currently coded temporal block 300ᵢ₋₁ shown in FIG. 5 (e.g., with the index shifted by one).

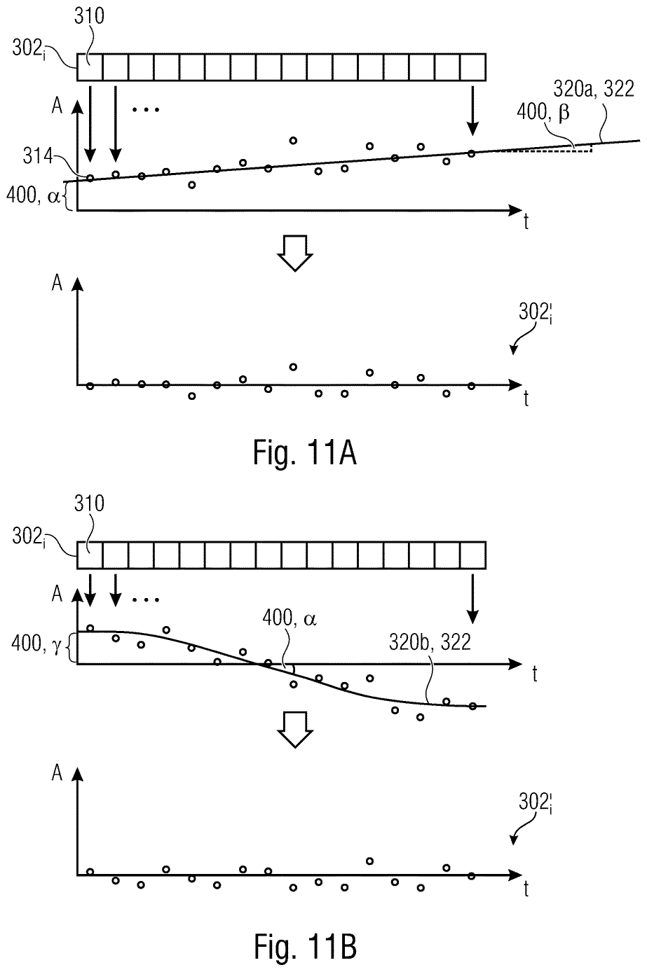

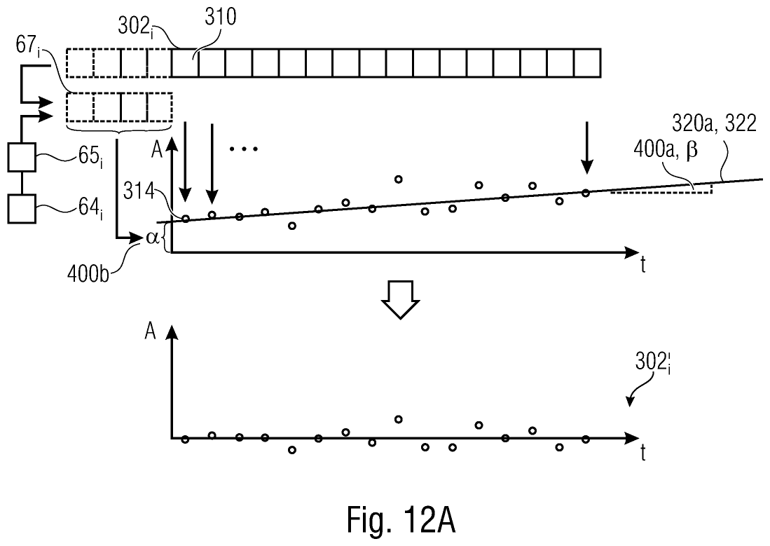

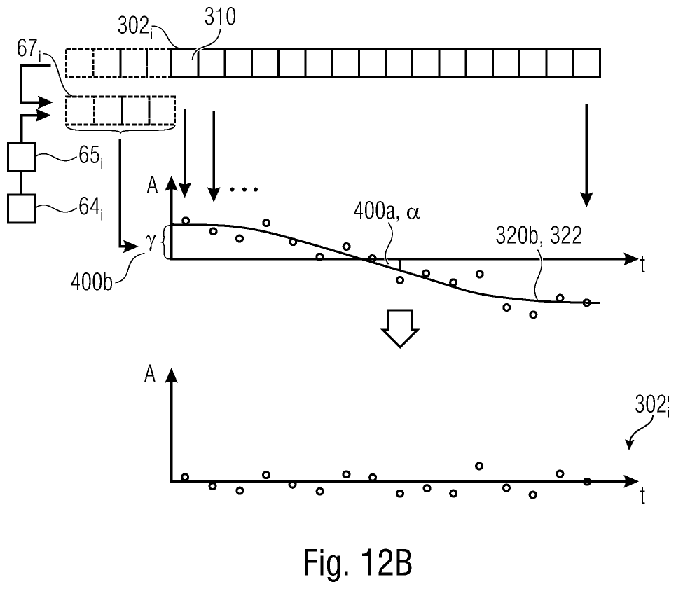

The decoder 12 may be configured to decode 402 one or more deblocking parameters 400 (e.g., one or two or more of a, B, and y described further below, e.g., with reference to FIG. 11A to 12B, e.g., with reference to section “Deblocking-Encoder Embodiment”) from the datastream 16, perform deblocking post-processing by modifying 404 the time-domain prediction residual signal 302ᵢ using the one or more deblocking parameters 400 to obtain a modified time-domain prediction residual signal 302′ᵢ, perform the correcting 308 the prediction signal 64ᵢ₋₁ using the modified time-domain prediction residual signal 302′ᵢ.

The one or more deblocking parameters 400 may define correction values (e.g., based on a function defined by the one or more deblocking parameters 400, e.g., wherein the correction values are values of the function at sample positions of the samples of the time-domain prediction residual signal 302ᵢ), wherein the modifying 404 the time-domain prediction residual signal 302ᵢ may comprise a linear combination (e.g., subtraction, sum, or weighted sum/subtraction) between the time-domain prediction residual signal 302ᵢ and the correction values (e.g., the function).

The one or more deblocking parameters 400 may define a linear function. For example, the deblocking parameters 400 may define an offset α and slope β (e.g., or only the slope β, e.g., wherein offset α is a further deblocking parameter derivable from previously decoded samples, as will be described further below), wherein the offset α and slope β define the linear function. For example, the offset α may define a vertical offset of the linear function, e.g., at a first sample position of the temporal block to be decoded, or at a second sample position immediately preceding said first sample, or a position between the first and second sample (e.g., not necessarily on a grid of sample positions, but at a finer granularity, such as sub-pel positions). The encoder 10 may be configured to determine offset α and slope β based on a mean μᵢₓ of a number of samples (e.g., N) of the temporal block 140ᵢ and a mean μᵣₑₛ of sample values of the time-domain prediction residual signal 302ᵢ using the following equation:

β=sumᵢ[(i−μᵢₓ)·(resᵢ−μᵣₑₛ)]/sumᵢ[(i−μᵢₓ)²], α=μᵣₑₛ−β·μᵢₓ with index 0≤i<N.

The one or more deblocking parameters (400) may define a trigonometric half-wave function parametrized by a half-wave offset (e.g., α) and an half-wave amplitude (e.g., γ). For example, the trigonometric half-wave function may be (or comprise) a cosine function ranging from 0 to π (e.g., from a value of +1 to −1), e.g., wherein the cosine function is parametrized (e.g., in an argument of the cosine function) to extend the half-wave thereof along the length of the temporal block 140 to be coded (e.g., having its maximum at a first sample and its minimum at a last sample, optionally shifted by a sub-pel position). The deblocking parameter for the half-wave amplitude (e.g., γ) may subsequently modify an amplitude of the cosine half-wave function (e.g., instead of covering a vertical range of two). The deblocking parameter for the half-wave offset (e.g., a) may define a vertical offset of the half-wave cosine function. Alternatively or additionally, the trigonometric half-wave function may be (or comprise) a sine function, e.g., ranging either from 0 to π (e.g., with a value range between 0 and 1) or, e.g., from π to 2π (e.g., with a value range between 0 and −1). This sine function—or, more precisely, half-sine function—may be more suitable than a half-cosine function if, e.g., the trans-formation applied to the given block signal already employs cosine functions as its basis functions.

The one or more deblocking parameters 400 (and optionally further deblocking parameters) may define a blocking-and-ringing-artefact-reducing function (e.g., the linear function or the trigonometric half-wave function as described herein, e.g., a function defining correction values dependent on sample positions) and the decoder 12 may be configured to modify 404 the time-domain prediction residual signal 302ᵢ using the one or more deblocking parameters 400 to obtain the modified the time-domain prediction residual signal 302′ᵢ by linearly combining (e.g. adding and/or e.g. subtracting) the blocking-and-ringing-artefact-reducing function and the time-domain signal 302′ᵢ. For example, in case of the blocking-and-ringing-artefact-reducing function being a linear function that is defined (at least) by the one or more deblocking parameters, wherein each sample of the time-domain prediction residual signal 302′ᵢ may be reduced by a corresponding correction value, which may be determined as a value of the function at a sample position of the corresponding sample of the time-domain prediction residual signal 302′ᵢ.

The one or more deblocking parameters 400 may comprise a gating flag which, if set, may indicate that the deblocking post-processing is active (e.g., if the gating flag has a value of one) and that the one or more deblocking parameters 400 comprise one or more function parameters defining a blocking-and-ringing-artefact-reducing function ought to be linearly combined (e.g. subjecting to an addition and/or e.g. subjecting to a subtraction) with the time-domain prediction residual signal 302ᵢ to obtain the modified time-domain prediction residual signal 302′ᵢ. If not set (e.g., if the gating flag has a value of zero), the gating flag may indicate that the deblocking post-processing is inactive, wherein the one or more deblocking parameters 400 may only comprise the gating flag, and the modified time-domain prediction residual signal 302′ᵢ may equal the time-domain prediction residual signal 302ᵢ. The gating flag may be signalled for each temporal block 140 or (e.g., once) for each set of temporal blocks 140 (e.g., for temporal block 30).

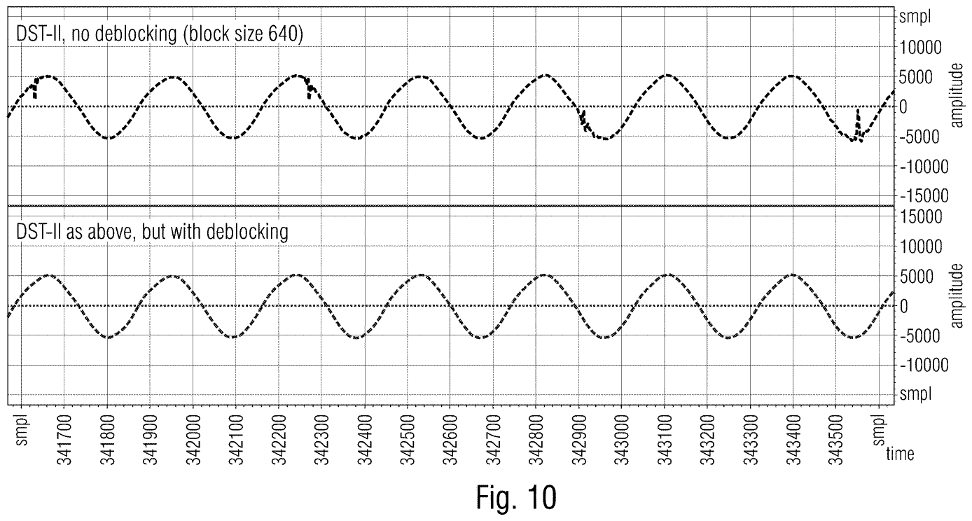

FIGS. 10a to 11b show different examples for modifying a time-domain prediction residual signal 302ᵢ. Any encoder 10 and/or decoder 12 disclosed herein may be configured to perform a modification as described with reference to FIG. 1A to 12B. The decoder 12 may be configured to decode 402 one or more deblocking parameters 400 from the datastream 16, perform deblocking post-processing by modifying the time-domain prediction residual signal 302ᵢ using the one or more deblocking parameters 400 to obtain a modified time-domain prediction residual signal 302′ᵢ, and perform the correcting 308 the prediction signal 64ᵢ using the modified time-domain prediction residual signal 302′ᵢ. Similarly, any encoder 10 disclosed herein may be configured to determine and encode the one or more deblocking parameters 400 into the datastream 16.

FIG. 11A shows a schematic view of samples 310 of a time-domain prediction residual signal 302ᵢ (e.g., for a temporal channel block 140ᵢ, e.g., any temporal block 140 described herein) before and after modification using one or more deblocking parameters α, β. In the example shown in FIG. 11A, a total of two deblocking parameters α, β are used, wherein both deblocking parameters α, β are derived from the data stream 16 (e.g., explicitly signaled or indirectly derivable from signaled information pertaining to the deblocking parameters α, β such as an index for a look-up table in which the deblocking parameters can be identified using the index). However, any other number of deblocking parameters may be used. Furthermore, one or more deblocking parameters (e.g., in form of a further deblocking parameter) may be derivable from previously coded samples 310 (e.g., instead of being derived directly from the data stream 16) as will be described further below (e.g., with reference to FIG. 12A, B).

In FIG. 11A, a horizontal axis t corresponds to a time axis and vertical axis A corresponds to an amplitude of samples values 314 of samples 310. Furthermore, an exemplary time-domain prediction residual signal 302ᵢ with 16 samples 310 is used. However, the time-domain prediction residual signal 302ᵢ may have any other number of samples 310. In the following examples, it is assumed that a sample value 314 is arranged in a middle (or center) of a time span of the corresponding sample 310. However, any other temporal position of sample values 314 (e.g., at the beginning, end, or anywhere in between) within the time span of corresponding samples 310 may be used instead.

The deblocking parameters α, β (see also reference sign 400) define a linear function 320a, wherein a defines a vertical offset (e.g., for example a function value for t=0) and β defines a slope. The linear function 320a may be determined (e.g., by the encoder 10) based on a simple linear regression of the 16 samples 310 of the time-domain prediction residual signal 302 (e.g., based on a mean μᵢₓ of a number of samples (e.g., N) of the temporal block 140ᵢ and a mean μᵣₑₛ of sample values of the time-domain prediction residual signal 302ᵢ). However, any other linear regression and number of samples 310 may be used instead. The linear function 320a may form (or form a basis for) a blocking-and-ringing-artefact-reducing function 322, which allows modifying the time-domain prediction residual signal 302j.

In the example shown in FIG. 11A, a modified time-domain prediction residual signal 302′ᵢ, is obtained by subtracting the blocking-and-ringing-artefact-reducing function 322 from the time-domain signal 302′ᵢ (or any other combination or linear combination). For example, the subtraction may be performed sample-wise between a sample 310 and a correction value of the blocking-and-ringing-artefact-reducing function 322 at a sample position of the corresponding sample 310. Since the blocking-and-ringing-artefact-reducing function 322 can be defined by the deblocking parameters α, β, the deblocking parameters α, β may need to be signaled in order to obtain the modified time-domain prediction residual signal 302′ᵢ. Due to the modification, the modified time-domain prediction residual signal 302′ᵢ may have reduces sample values at the end and the beginning, which may reduce blocking and ringing artefacts. Values of the blocking-and-ringing-artefact-reducing function 322 at a (e.g., temporally) first and last sample 310 of the time-domain prediction residual signal 302ᵢ may be referred to as anchor values or anchor parameters (e.g., starting anchor value for a left-most sample (e.g., sample index i=0) and ending anchor value for a right-most sample (e.g., sample index i=N−1) of the time-domain prediction residual signal 302ᵢ.

FIG. 11B shows a schematic view of samples 310 of a time-domain prediction residual signal 302ᵢ having a cosine-like shape before and after modification using one or more deblocking parameters α, γ. One or both deblocking parameters α, γ may be derived from the data stream 16, and the deblocking parameters α, γ may be used to define a half-cosine angular function 320b (e.g., a cosine function extending half a period, e.g., or any other trigonometric half-wave function). Generally, the one or more deblocking parameters 400 may define a trigonometric half-wave function parametrized by a half-wave offset (e.g., α) and an half-wave amplitude (e.g., γ). The half-cosine angular function 320b may be defined as α+γ cos (i*π/N). For example, a may define a half-wave offset (e.g., defining a vertical offset) and γ may define a half-wave amplitude (e.g., a scalar to be multiplied with a cosine function). However, any other number of deblocking parameters and any other way to parametrize a trigonometric function may be used instead. The half-cosine angular function 320b may form (or form a basis for) a blocking-and-ringing-artefact-reducing function 322, which allows modifying the time-domain prediction residual signal 302ᵢ. Similarly as described above, a modified time-domain prediction residual signal 302′ᵢ, may be obtained by subtracting the blocking-and-ringing-artefact-reducing function 322 from the time-domain signal 302′ᵢ (or any other combination of linear combination).

The encoder 10 and decoder 12 may be configured to determine only one type of blocking-and-ringing-artefact-reducing function 322 (e.g., only a linear function 320a or only a trigonometric half-wave function 320b), in which case, a signalling of a type of a blocking-and-ringing-artefact-reducing function 322 may not be required. Alternatively, the encoder 10 and decoder 12 may be configured to determine more than one type of blocking-and-ringing-artefact-reducing function 322, in which case, the encoder 10 may be configured to decoder an indicator (e.g., an index or flag), for indicating the type of the blocking-and-ringing-artefact-reducing function 322 to be used. For example, the encoder 10 may be configured to test (or simulate) more than one (e.g., all) types of blocking-and-ringing-artefact-reducing function 322 for a time-domain prediction residual signal 302ᵢ, select one type (e.g., based on one or more of detection of ringing artefacts, distortion, and a variance measure of the modified time-domain prediction residual signal 302′ᵢ). The encoder 10 may subsequently encode an identifier of the type of blocking-and-ringing-artefact-reducing function 322 and one or more deblocking parameters 400.

As has been shown exemplarily above, both deblocking parameters 400 may be derived or obtained from the data stream 16. However, at least one further deblocking parameter may be derived from previously coded samples. The decoder 12 may be configured to derive a further deblocking parameter based on already coded samples of the digital time-varying signal (e.g., based on one, two, three, or more samples that immediately precede the respective transform-coded temporal block 140ᵢ, e.g., within the same channel).

FIG. 12A, B show examples a schematic view of sample modification using a further deblocking parameter 400b, a derived from previously coded samples 310.

The decoder 12 may be configured to determine a further deblocking parameter based on the prediction signal 64ᵢ (e.g., a left-most or temporally earliest sample thereof) of the respective transform-coded temporal block 140ᵢ and one or more already coded samples of the digital time-varying signal (e.g., based on one, two, three, or more already coded samples that immediately precede the respective transform-coded temporal block 140ᵢ, e.g., within the same channel, e.g., without decoding the further deblocking parameter 400b from the data stream 16), and perform the deblocking post-processing by modifying 404 the time-domain prediction residual signal 302ᵢ using the one or more deblocking parameters 400a (e.g., exactly one deblocking parameter) and the further deblocking parameter 400b (e.g., exactly one further deblocking parameter) to obtain the modified time-domain prediction residual signal 302′ᵢ).

The decoder 12 may be configured to determine an extension of the prediction signal 64ᵢ (e.g., in a direction towards the one or more already coded samples, e.g., towards earlier samples within the time-domain) of the digital time-varying signal (e.g., a linear extrapolation, e.g., an extension or expansion of the prediction signal 64ᵢ by additional samples temporally preceding the original prediction signal 64ᵢ). The decoder 12 may further be configured to combine (e.g., linearly combine, e.g., perform a subtraction between) the extension of the prediction signal 64ᵢ and the one or more already coded samples of the digital time-varying signal in order to obtain a modified version of the one or more already coded samples, and to determine the further deblocking parameter 400b based on an extrapolation (e.g., a linear extrapolation) of the modified version of the one or more already coded samples (e.g., determine the further deblocking parameter 400b based on a value of the extrapolation at a temporally first sample of the prediction signal 64ᵢ). For example, the modified version of the one or more already coded samples may be or may be based on the one or more already coded samples of the digital time-varying signal, from which, sample-wise, the extension of the prediction signal 64ᵢ has been subtracted.

The decoder 12 may be configured to determine an extrapolation of a plurality (e.g., three, four, five, or more) of already coded samples that (e.g., immediately, e.g., temporally) precede the respective transform coded temporal block 140ᵢ (e.g., a linear extrapolation), and

determine the further deblocking parameter 400b based on the extrapolation of the plurality of already coded samples and the prediction signal 64ᵢ (e.g., a temporally first sample of the prediction signal 64ᵢ, e.g., based on a difference between the extrapolation and a value of the temporally first sample). In other words, the prediction signal may be extended towards the previously coded samples and modified based on said previously coded samples or may extend the previously coded samples towards the prediction signal and modify the extension based on the prediction signal. However, other approaches may be used in order to determine a modified extension or extrapolation (e.g., using a combination of both approaches). The further deblocking parameter 400b may be determined as (or based on) a value of the modified extension or extrapolation at a temporally first (or leftmost) sample of the temporal block 140 (or of the prediction signal 64ᵢ), e.g., at a center position of the sample or at a sub-pel offset (e.g., half or quarter sample) in a temporal forward or backwards direction.

The blocking-and-ringing-artefact-reducing function may be defined by the one or more deblocking parameters 400a (e.g., by exactly one deblocking parameter, e.g., B) and by the further deblocking parameter 400b (e.g., by exactly one further deblocking parameter, e.g., a).

The further deblocking parameter 400b and the one or more deblocking parameters 400a may define a linear function 320a (e.g., wherein the further deblocking parameter 400b defines a vertical offset of the linear function 320a).

FIG. 12A shows a schematic view of samples 310 of a time-domain prediction residual signal 302ᵢ before and after modification using a deblocking parameter 400a, β derived from the data stream 16, and a further deblocking parameter 400b, a derived from previously coded samples 310 and the prediction signal 64ᵢ.

In one embodiment, the decoder 12 is configured to determine an extension 65ᵢ of the prediction signal 64ᵢ (e.g., in a direction towards the one or more already coded samples, e.g., towards earlier samples within the time-domain) of the digital time-varying signal. The extension 65ᵢ may be formed by (or on a basis of) a linear extrapolation of the prediction signal 64ᵢ (e.g., a regressive linear extrapolation). Alternatively, the extension 65ᵢ may be formed by (or on a basis of) adding further already coded samples temporally preceding the original prediction signal 64ᵢ (e.g., increasing the length of the prediction signal 64ᵢ from 16 samples to 20 samples). The decoder 12 may further be configured to combine (e.g., linearly combine, e.g., perform a sample-wise subtraction between) the extension of the prediction signal 64ᵢ and the one or more already coded samples (e.g., four samples in the example shown in FIG. 12A) of the digital time-varying signal in order to obtain a modified version 67ᵢ of the one or more already coded samples (e.g., by sample-wise subtracting four samples of the extension 65ᵢ from four immediately preceding already coded samples). The decoder 12 may further be configured to perform the deblocking post-processing by modifying 404 the time-domain prediction residual signal 302ᵢ using the one or more deblocking parameters 400a (e.g., exactly one deblocking parameter as shown in FIG. 12A) and the further deblocking parameter 400b (e.g., exactly one further deblocking parameter as shown in FIG. 12A) to obtain the modified time-domain prediction residual signal 302′ᵢ. For example, the encoder 12 may be configured to perform an extrapolation of the (e.g., four) samples of the modified version 67ᵢ of the one or more already coded samples. The extrapolation can subsequently be used to determine the further deblocking parameter 400b, for example, in form of a left anchor parameter, by determining a value of the extrapolation the beginning of the respective transform-coded temporal block 140ᵢ. The beginning may depend on a coordinate system for the linear function 320a. For example, if the linear function 320a is defined according to α+βt, then α may be determined (or approximated) by using the time t=0 of the coordinate system of said linear equation in the extrapolation of the modified version 67ᵢ.

The approach described above is one of many ways to determine (or estimate) the further deblocking parameter 400b. In a simpler version, the further deblocking parameter α may be determined based on a difference between a sample value of a sample 310 immediately preceding a first (e.g., temporally first) sample 310 of the temporal block 140 to be decoded and a first sample of the prediction signal 64ᵢ (e.g., if the temporal block 140 to be decoded has N samples indexed by sample index i=0 to N−1, a difference between already decoded sample at sample index i=−1 and a sample of the prediction signal 64ᵢ at i=0). In another example, the further deblocking parameter α may be derived using an extrapolation (e.g., linear regressive extrapolation) of samples of a plurality (e.g., two, three, four, five, or more) samples 310 that immediately precede (e.g., with sample index i=−4 to −1) the respective transform coded temporal block (140ᵢ), wherein the further deblocking parameter β is determined based on a difference between a value of the extrapolation at a temporal position of the a first sample of the prediction signal 64ᵢ on the one hand and a sample value of the first sample of the prediction signal 64ᵢ on the other hand. In a different example, the deblocking parameter α may be determined based on a central tendency (e.g., an average, weighted average, or median) of a plurality of previously coded samples 310 (e.g., immediately preceding samples 310). The further deblocking parameter 400b may be determined to minimize an (e.g., absolute) value of a (e.g., temporally) first sample of the modified time-domain prediction residual signal 302′ᵢ (e.g., reduce the value to zero or close to zero, e.g., reduce an absolute value by more than 75%, 90% or 95%). Samples values of zero may be assumed for the already coded samples of the digital time-varying signal, if no already coded samples of the digital time-varying signal are available (e.g., at the start of a coding procedure, e.g., due to restriction in coding dependencies, for example, when coding in a random access manner independent from previous temporal blocks 30).

Since deblocking can be realized by reducing the residual signal (or rather the modified version 302′ᵢ thereof) to zero or close to zero, which can effectively be obtained by removing a value of the residual, which, in turn, can be estimated based on previously decoded samples. In other words, the similarity in sample values in the vicinity of already decoded samples can be exploited for determining the further deblocking parameter. Therefore, transmission of the further deblocking parameter α may be omitted, which may improve coding efficiency. For example, only the deblocking parameter β may be (e.g., directly or indirectly) transmitted in the data stream 16, whereas the deblocking parameter α may not be transmitted and instead be derived based on previously coded samples 130. It is noted that any other number of previously decoded samples 130 (e.g., two, three, five, six, or more) may be used to derive the further deblocking parameter α.

The further deblocking parameter 400b and the one or more deblocking parameters 400a may define a trigonometric half-wave function 320b (e.g., cosine or sine half-wave function) parametrized by a half-wave offset and an half-wave amplitude (e.g., wherein the further deblocking parameter 400b defines a scaling factor for an amplitude of the trigonometric half-wave function 320b).

FIG. 12B shows a schematic view of samples 310 of a time-domain prediction residual signal 302ᵢ having a cosine-like shape before and after modification using a deblocking parameter α derived from the data stream 16, and a further deblocking parameter y derived from previously coded samples 310. The deblocking parameter y may be determined based on the prediction signal 64ᵢ and one or more immediately preceding (e.g., temporally, e.g., in the same channel) decoded samples 310. For example, the deblocking parameter y may be determined based on an extrapolation of a modified version 67ᵢ of already coded samples or any other approach as described herein. For example, a received deblocking parameter α may vertically offset the half-cosine angular function 320b, which can be scaled so as to match at a leftmost sample (e.g., the first of the 16 samples of the time-domain prediction residual signal 302ᵢ shown in FIG. 12B) a value derived from an extrapolation of a modified version 67ᵢ of already coded samples.

The bitstream 16 may comprise one or more syntax elements (e.g., one or more flags) that indicate whether the deblocking parameters (and optionally the further deblocking parameters) define a linear function or a trigonometric function (e.g., half-cosine angular function). The bitstream 16 may comprise one or more syntax elements (e.g., one or more flags) that indicate whether a further syntax element is to be derived based on previously coded samples 40. Alternatively, the type of function and/or use of a further syntax element may be pre-configured.

Further, adaptive filtering with signaled filter coefficients might be used to filter either the weighted sum of individual weighted reference block portions, or one or more of the reference block portions before being used to form the prediction signal in combination with the other reference block portion(s).

Further is provided an encoder (for example, but not limited to, encoder 10 shown in FIG. 1, 4A, 4B, 8C, or 9) for encoding a digital time-varying signal 92 into a data stream 16, configured to encode the digital time-varying signal 92 from the data stream 16 in non-overlapping temporal blocks 140 by encoding each of transform-coded temporal blocks 140ᵢ₋₁ of the non-overlapping temporal blocks 140 of the digital time-varying signal 92 by predicting the respective transform-coded temporal block 140ᵢ₋₁ using a selected prediction mode out of a set of prediction modes to obtain a prediction signal 64ᵢ₋₁, subjecting a time-domain prediction residual signal 302ᵢ₋₁ representing a prediction residual signal 80 of the respective transform-coded temporal block 140ᵢ in a time domain to a predetermined transformation from the time domain to a transform domain to obtain coefficients 300ᵢ₋₁ representing the prediction residual signal 80 of the respective transform-coded temporal block 140ᵢ₋₁ in the transform domain, and encoding the coefficients 300ᵢ₋₁ into the data stream 16 so as to be used for correcting 308 the prediction signal 64ᵢ₋₁, wherein the predetermined transformation is a non-overlapping transform.

The encoder 10 may be configured to encode a data stream 16 decodable by any decoder 12 disclosed herein.

For example, the predetermined transformation (e.g. Tᵢ₋₁) is a discrete cosine transform or a discrete sine transform. The encoder 10 may be configured to select the predetermined transformation out of a set of transformations. The encoder 10 may be configured to subject the time-domain prediction residual signal 302ᵢ₋₁ to the predetermined transformation in a manner independent from a prediction residual signal 80 of temporally adjacent temporal blocks 140ᵢ, 140ᵢ₋₂, preceding and following the respective transform-coded temporal block 140ᵢ₋₁. The encoder 10 may be configured to support different lengths of the transform-coded temporal blocks, and select and encode a length parameter in the data stream, wherein a switching between different lengths of the transform-coded temporal blocks is performed at predetermined borders between consecutive temporal blocks. The encoder 10 of may be configured to perform a deblocking pre-processing by determining one or more deblocking parameters 400, modifying 404 the time-domain prediction residual signal 302′ᵢ₋₁ of the respective transform-coded temporal block 140ᵢ₋₁ using the one or more deblocking parameters 400 (e.g., one or more of deblocking parameter 400a and further deblocking parameter 400b) to obtain a modified time-domain prediction residual signal 302ᵢ₋₁, subjecting 306 the modified time-domain prediction residual signal 302ᵢ to the predetermined transformation from the time domain to the transform domain to obtain coefficients 300ᵢ, wherein the transformation is a non-overlapping transform.

The encoder 10 may be configured to perform a deblocking pre-processing by determining one or more deblocking parameters 400, modifying 404 the time-domain prediction residual signal 302′ᵢ of the respective transform-coded temporal block 140ᵢ using the one or more deblocking parameters 400 to obtain a modified time-domain prediction residual signal 302ᵢ, subjecting 306 the modified time-domain prediction residual signal 302ᵢ to the predetermined transformation from the time domain to the transform domain to obtain coefficients 300ᵢ, wherein the transformation is a non-overlapping transform.

The one or more deblocking parameters 400 may define a blocking-and-ringing-artefact-reducing function (e.g., a linear function or a trigonometric half-wave function), and the encoder may be configured to modify 404 the time-domain prediction residual signal 302′ᵢ using the one or more deblocking parameters 400 by linearly combining (e.g. subjecting to a subtraction and/or e.g. subjecting to an addition) the blocking-and-ringing-artefact-reducing function and the time-domain prediction residual signal 302′ᵢ and determine the one or more deblocking parameters so that the linearly combining (e.g. subjecting to a subtraction) the blocking-and-ringing-artefact-reducing function and the time-domain prediction residual signal 302′ᵢ results in the modified time-domain prediction residual signal 302ᵢ getting zero at a leading and trailing end of the respective transform-coded temporal block 140ᵢ, or getting closer to zero than a predetermined maximum distance, or in the modified time-domain prediction residual signal 302ᵢ getting a zero mean slope within respective transform-coded temporal block 140ᵢ, or in a mean slope of the modified time-domain prediction residual signal 302ᵢ getting closer to zero than a predetermined maximum deviation.

The one or more deblocking parameters 400 may define a blocking-and-ringing-artefact-reducing function, wherein the encoder 10 may be configured to modify 404 the time-domain prediction residual signal 302′ᵢ using the one or more deblocking parameters 400 by linearly combining (e.g. subjecting to a subtraction and/or e.g. subjecting to an addition) the blocking-and-ringing-artefact-reducing function and the time-domain prediction residual signal 302′ᵢ. The encoder 10 may be configured to determine a statistical dispersion value of the time-domain prediction residual signal 302′ᵢ, if the statistical dispersion value (e.g., based on a variance of the samples of the residual signal, e.g., a variance of a high-pass filtered version of the residual signal, e.g., compared to a variance of a non-high-pass filtered version of the residual signal) falls into a value range (e.g., having a lower and upper threshold) being indicative of a smooth signal (e.g., ratio of variances not exceeding a threshold), determine the one or more deblocking parameters so (e.g., defining anchor points) that the linearly combining (e.g. subjecting to a subtraction and/or e.g. subjecting to an addition) the blocking-and-ringing-artefact-reducing function and the time-domain prediction residual signal 302′ᵢ results in the modified time-domain prediction residual signal 302ᵢ getting zero at a leading and trailing end of the respective transform-coded temporal block 140ᵢ, or getting closer to zero than a predetermined maximum distance.

If the statistical dispersion value falls into a value range (e.g., having a lower and upper threshold) being indicative of a non-smooth signal, determine the one or more deblocking parameters so that the linearly combining (e.g. subjecting to a subtraction and/or e.g. subjecting to an addition) the blocking-and-ringing-artefact-reducing function and the time-domain prediction residual signal 302′ᵢ results in the modified time-domain prediction residual signal 302ᵢ getting a zero mean slope within respective transform-coded temporal block 140ᵢ, or in a mean slope of the modified time-domain prediction residual signal 302ᵢ getting closer to zero than a predetermined maximum deviation.

The encoder 10 may be configured to determine a noisiness measure (e.g. zero-crossing-rate, e.g., a number of or indicative of how often the signal crosses a value of zero) of the time-domain signal 302′ᵢ, if the noisiness measure falls into a value range (e.g., having a lower and upper threshold) being indicative of a noisy signal, not set a gating flag (e.g., in order to avoid high-cost cases) comprised by the one or more deblocking parameters 400 so as to indicate that the deblocking pre-processing is inactive so that the one or more deblocking parameters 400 only comprise the gating flag, and the modified time-domain prediction residual signal 302ᵢ equals the time-domain signal 302′ᵢ, or set one or more function parameters which define a blocking-and-ringing-artefact-reducing function ought to be linearly combined (e.g. subjecting to a subtraction and/or e.g. subjecting to an addition) with the time-domain prediction residual signal 302′ᵢ to obtain the modified time-domain prediction residual signal 302ᵢ and are comprised by the one or more deblocking parameters so that the blocking-and-ringing-artefact-reducing function is zero so that that a deblocking is effectively disabled.

If the noisiness measure does not fall into the value range being indicative of a noisy signal, the encoder 10 may be configured to determine the one or more function parameters so that so that the linearly combining (e.g. subjecting to a subtraction) the blocking-and-ringing-artefact-reducing function and the time-domain signal 302′ᵢ results in the modified time-domain prediction residual signal 302ᵢ getting zero at a leading and trailing end (e.g., within the time domain) of the respective transform-coded temporal block 140ᵢ, or getting closer to zero than a predetermined maximum distance, or in the modified time-domain signal 302ᵢ getting a zero mean slope within respective transform-coded temporal block 140j, or in a mean slope of the modified time-domain prediction residual signal 302ᵢ getting closer to zero than a predetermined maximum deviation.

The encoder 10 may be configured to encode the one or more deblocking parameters 400 in the data stream 16. However, the encoder 10 may be configured to not encode further deblocking parameters 400b.

The encoder 10 may be configured to determine a further deblocking parameter 400b based on the prediction signal 64ᵢ of the respective transform-coded temporal block 140ᵢ and one or more already coded samples of the digital time-varying signal (e.g., based on one, two, three, or more already coded samples that immediately precede the respective transform-coded temporal block 140ᵢ, e.g., within the same channel, e.g., without encoding the further deblocking parameter 400b in the data stream 16), and perform the deblocking post-processing by modifying 404 the time-domain prediction residual signal 302ᵢ using the one or more deblocking parameters 400a (e.g., exactly one deblocking parameter) and the further deblocking parameter 400b (e.g., exactly one further deblocking parameter) to obtain the modified time-domain prediction residual signal 302′_{i.}

The encoder 10 may be configured to determine an extension of the prediction signal 64ᵢ (e.g., in a direction towards the one or more already coded samples, e.g., towards earlier samples within the time-domain) of the digital time-varying signal (e.g., a linear extrapolation, e.g., an extension or expansion of the prediction signal 64ᵢ by additional samples temporally preceding the original prediction signal 64ᵢ), combine (e.g., linearly combine, e.g., perform a subtraction between) the extension of the prediction signal 64ᵢ and the one or more already coded samples of the digital time-varying signal in order to obtain a modified version of the one or more already coded samples, and determine the further deblocking parameter 400b based on an extrapolation (e.g., a linear extrapolation) of the modified version of the one or more already coded samples (e.g., determine the further deblocking parameter 400b based on a value of the extrapolation at a temporally first sample of the prediction signal 64ᵢ).

The encoder 10 may be configured to determine an extrapolation (e.g., in a direction towards the respective transform-coded temporal block 140ᵢ) of a plurality (e.g., three, four, five, or more) of already coded samples that (e.g., immediately, e.g., temporally) precede the respective transform coded temporal block 140ᵢ (e.g., a linear extrapolation), determine the further deblocking parameter 400b based on the extrapolation of the plurality of already coded samples and the prediction signal 64ᵢ (e.g., a temporally first sample of the prediction signal 64ᵢ, e.g., based on a difference between the extrapolation and a value of the temporally first sample).

The further deblocking parameter 400b and the one or more deblocking parameters 400a may define a linear function 320a (e.g., wherein the further deblocking parameter 400b defines a vertical offset of the linear function 320a).

The further deblocking parameter 400b and the one or more deblocking parameters 400a define a trigonometric half-wave function 320b parametrized by a half-wave offset and an half-wave amplitude (e.g., wherein the further deblocking parameter 400b defines a scaling factor for an amplitude of the trigonometric half-wave function 320b).

The blocking-and-ringing-artefact-reducing function may be defined by the one or more deblocking parameters 400a (e.g., by exactly one deblocking parameter) and by the further deblocking parameter 400b (e.g., by exactly one further deblocking parameter).

The further deblocking parameter 400b is determined to minimize an (e.g., absolute) value of a (e.g., temporally) first sample of the modified time-domain prediction residual signal 302′ᵢ (e.g., reduce the value to zero or close to zero, e.g., reduce an amplitude by more than 75%, 90% or 95%).

Generally, and using a pseudo-code like writing, the following options for transmitting the reference block portions' offsets and the filter decision shall explicitly be mentioned (with steps in parenthesis being optional):

```
A)
(decode/encode number of reference block portions) (NOTE: for this temporal block
individually or at a larger temporal scope)
For each reference block portion
  decode/encode offset unit indicator (NOTE: one of full-sample, half-sample units or
the like)
  decode/encode number of offset units (NOTE: so that offset is this number
times offset unit)
if there is no reference block portion with sub-sample offset, (NOTE: that is, no
reference block portion which requires interpolation filter)
decode/encode filter flag
if there is a reference block portion with sub-sample offset,
infer that the filter flag indicates no filtering
if filter flag indicates filtering,
decode/encode filter information (NOTE: this filter might be applied to weighted sum to
yield final prediction signal 64)
B)
(decode/encode number of reference block portions) (NOTE: for this temporal block
individually or at a larger temporal scope)
decode/encode offset unit indicator (NOTE: one of full-sample, half-sample units or the
like)
For each reference block portion
  decode/encode number of offset units (NOTE: so that offset is this number
times offset unit)
if there is no reference block portion with sub-sample offset, (NOTE: that is, no
reference block portion which requires interpolation filter)
decode/encode filter flag (NOTE: otherwise it may deemed to be none-indicative of
filtering)
if filter flag indicates filtering,
decode/encode filter information (NOTE: this filter might be applied to weighted sum to
yield final prediction signal 64)
C)
(decode/encode number of reference block portions) (NOTE: for this temporal block
individually or at a larger temporal scope)
decode/encode filter flag
if filter flag indicates filtering,
decode/encode filter information (NOTE: this filter might be applied to weighted sum to
yield final prediction signal 64)
  infer that offset unit indicator of each temporal block portion indicates full-sample
offset unit
if filter flag not indicates filtering,
For each reference block portion
if filter flag not indicates filtering,
  decode/encode offset unit indicator (NOTE: one of full-sample, half-sample units or
the like)
  decode/encode number of offset units (NOTE: so that offset is this number
times offset unit)
D)
(decode/encode number of reference block portions) (NOTE: for this temporal block
individually or at a larger temporal scope)
For each reference block portion
decode/encode offset unit indicator (NOTE: one of full-sample, half-sample units or the
like)
decode/encode number of offset units (NOTE: so that offset is this number times
offset unit)
if respective block portion has no sub-sample offset, (NOTE: that is, this reference
block portion does not require interpolation filter)
decode/encode filter flag
if filter flag indicates filtering,
decode/encode filter information (NOTE: otherwise no filtering (except interpolation
filtering) takes place)
E)
(decode/encode number of reference block portions) (NOTE: for this temporal block
individually or at a larger temporal scope)
For each reference block portion
  decode/encode offset unit indicator (NOTE: one of full-sample, half-sample units or
the like)
  decode/encode number of offset units (NOTE: so that offset is this number
times offset unit)
decode/encode filter flag
if filter flag indicates filtering,
decode/encode filter information (NOTE: this filter might be applied to weighted sum to
yield final prediction signal 64)
F)
(decode/encode number of reference block portions) (NOTE: for this temporal block
individually or at a larger temporal scope)
decode/encode offset unit indicator (NOTE: one of full-sample, half-sample units or the
like)
For each reference block portion
  decode/encode number of offset units (NOTE: so that offset is this number
times offset unit)
decode/encode filter flag
if filter flag indicates filtering,
decode/encode filter information (NOTE: this filter might be applied to weighted sum to
yield final prediction signal 64)
G)
(decode/encode number of reference block portions) (NOTE: for this temporal block
individually or at a larger temporal scope)
For each reference block portion
decode/encode offset unit indicator (NOTE: one of full-sample, half-sample units or the
like)
decode/encode number of offset units (NOTE: so that offset is this number times
offset unit)
decode/encode filter flag
if filter flag indicates filtering,
decode/encode filter information (NOTE: otherwise no filtering (except, potentially,
interpolation filtering) takes place)
```

As described in FIG. 1, the datastream 16 has a prediction residual 80 encoded thereinto which forms the prediction residual of prediction signal 64 and might be used to correct prediction signal 64, such as by addition, to yield the reconstruction of temporal block 140.

The above description is extended in the following by the presentation of further embodiments.

The following section may be titled “Perceptual coding and decoding of biomedical, seismic, and related waveform signals”

Two-dimensional (e.g., with time as one dimension and amplitude as second dimension) waveform signals such as those recorded in, e. g., seismic, biomedical or sonar contexts are usually, when stored or transmitted in a digital representation, coded losslessly. However, lossy coding may be desirable as well in some situations, especially when an objective is to reduce the bit-rate required for the single- or multi-channel waveform signals in question. Such lossy coding typically may involve the use of time-frequency transforms (on encoder side, e.g., transformation) and frequency-time (i. e., inverse) transforms (on decoder side, e.g., re-transformation), applied on a block level, to maximize the coding gain and/or to allow for perceptually optimized encoding.

### Shortcoming of Traditional Transform Coding

One drawback of the usage of forward and inverse block transforms in lossy waveform coding is the occurrence of blocking or ringing artefacts after relatively coarse requantization of the transform coefficients, related to Gibbs' phenomenon (a detailed explanation of which is given at https://en.wikipedia.org/wiki/Gibbs phenomenon). Such artefacts may be perceived in some signals even when a waveform block-signal subjected to the transformation is the residual of a prediction operation (e.g., prediction residual signal), e.g., a sample-wise difference signal between an original waveform block (e.g., transform-coded temporal block) and a prediction block (e.g., prediction signal, e.g., constructed from previously decoded and reconstructed waveform parts), where the prediction block may be of the same size as the original waveform block.

### Conventional Solutions and Their Drawbacks

There are, for example, two frequently employed algorithms to address the issue of blocking and ringing in lossy media coding. The first, the application of lapped transforms such as the type-IV modified discrete cosine transform (MDCT) and its inverse counterpart (IMDCT), results in overlap among the frame signals and, thereby, increased encoder/decoder (codec) delay and waveform reconstruction complexity especially at the beginning of a waveform and/or between two successive but independently coded waveforms (see also https://en.wikipedia.org/wiki/Gapless playback). In addition, the combination of lapped transforms and predictive coding (i. e., lapped transformation of prediction residual block-signals) is complicated and only feasible in restricted form: the prediction signal must be extended in time (size) to also cover the transform overlap range.

The second algorithm to reduce blocking artefacts, employed in many image and video codecs, is a deblocking post-filter, applied after inverse transformation (e.g., re-transformation) and picture reconstruction. This solution may work well on multi-dimensional (time-space-amplitude) natural image and video data captured by digital cameras but exhibits two key shortcomings which reduce its effectiveness on the abovementioned two-dimensional waveform data as well as possibly on music or speech signals:
Deblocking does not scale well towards lossless or, in some cases, even perceptually transparent (i. e., near-lossless) coding since it generally operates “blindly” on the decoded and reconstructed signal samples and may be unable to distinguish between blocking artefacts and actual input data, hence potentially altering- and distorting-a near-lossless decoding.
Deblocking does not work well on waveform input with highly variant sample statistics, i. e., signals which are more fluctuating, or non-stationary, than still images or video sequences. On such signals, there is either too little deblocking being applied, or the deblocking itself may result in additional reconstruction artefacts. Evidently, both situations are undesirable.

### Summary of the Inventive (De)Coding Solution

In the following, a method and an apparatus are described which allow for transform encoding and corresponding decoding with optional predictive coding techniques but without transform overlap, allowing for a straightforward codec architecture and minimal risk of gapless playback issues, i. e., of wrong reconstructions especially in the first and last frames in a coded bitstream.

The invention comprises two aspects, which may be used individually or in combination. The first aspect is the use of a specific non-overlapping block transform (in the encoder) and corresponding non-overlapping block inverse transform (in the decoder), applied onto the residual (e.g., sample-wise result) of at least one predictive coding operation, e.g., in the encoding and decoding of a biomedical, seismic, or acoustic signal. In other words, due to said absence of inter-transform overlap, no temporal windowing and time-domain aliasing (TDA) (Another frequently used term for the TDA operation is “folding” or “folding-in”; analogously, the TDAC operation may also be called “folding-out”) operations, as commonly utilized in audio codecs, may need to be performed. Said specific non-overlapping block transform may be a discrete cosine or sine transform, advantageously a type-II DCT (also called DCT-2) or DST (also called DST-2) or resp. inverse counterpart thereof. It is noted that such DCTs and DSTs may be used in the AC-2 audio coding standard, but with transform overlap and no predictor (see https://ccrma.stanford.edu/~jos/Compression/Compression.pdf).

The second aspect is the utilization of a guided deblocking operation (e.g., perform deblocking post-processing) in said encoding and/or decoding of a biomedical, seismic, or acoustic signal, applied in a “forward” fashion, e.g., before forming the to-be-quantized residual block transform coefficients (in the encoder) according to aspect 1, and in a corresponding “inverse” fashion during transform coefficient reconstruction (in the decoder). The guided deblocking operation comprises the transmission (i. e., signaling) of one or two deblocking parameters (or more deblocking parameters) per transform block, for example, in a quantized form. Said (one or more) deblocking parameters may be converted, e.g., into an offset and a slope or curvature value, from which a sample-wise monotonically increasing or decreasing corrective function may be determined and may be, subsequently, applied (e.g., equally) to the initial residual block samples in the encoder (e. g., via subtraction) as well as the reconstructed residual block samples in the decoder (e. g., via addition).

### Detailed Description of Aspect 1: Architecture

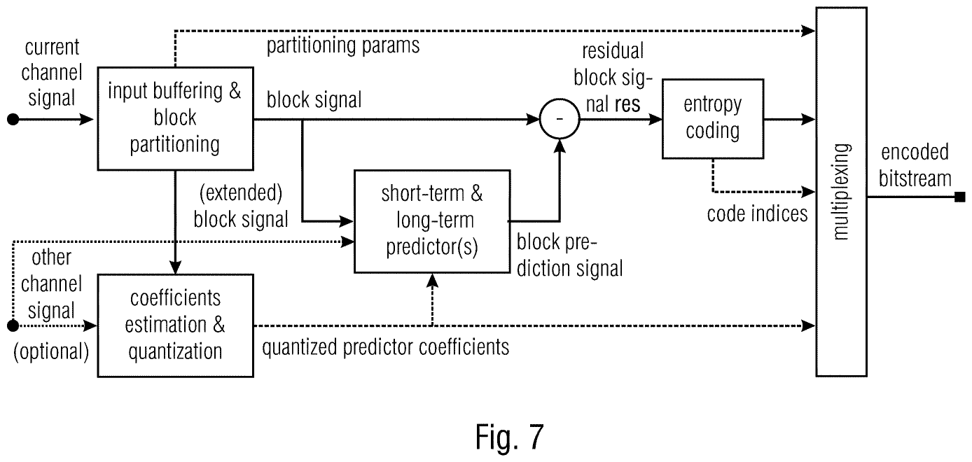

FIG. 7 depicts a block diagram of a typical linear predictive coding (LPC) based lossless audio encoder [1]. Here, the block-wise prediction residual may not be time-frequency transformed or re-quantized, e.g., so as to achieve lossless compression, i. e., perfect signal reconstruction during the decoding process. It is noted that a ‘Predictor’ block may represent one or more (e.g., in the latter case cascaded or combined) short-term, long-term, or cross-channel prediction signal generators. To be specific, such a predictor may be, e.g., a short-term predictor (also called LPC predictor) utilizing previous samples in the near past; or, e.g., a long-term predictor, also called LTP or, equivalently in video coding, motion compensation, e.g., utilizing a block of (previous) samples in a more distant past; or in case of multi-channel signals, e.g., a cross-channel or cross-component predictor, e.g., using (current or previous) samples in at least one other channel or component of the encoded signal.

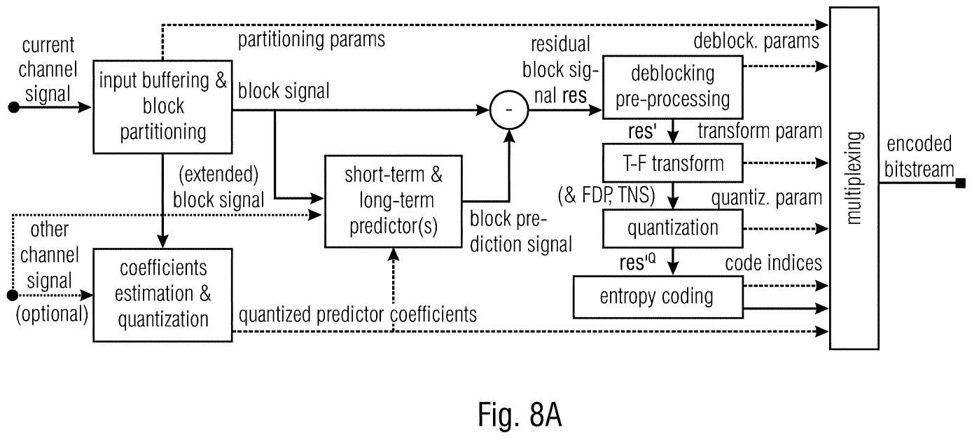

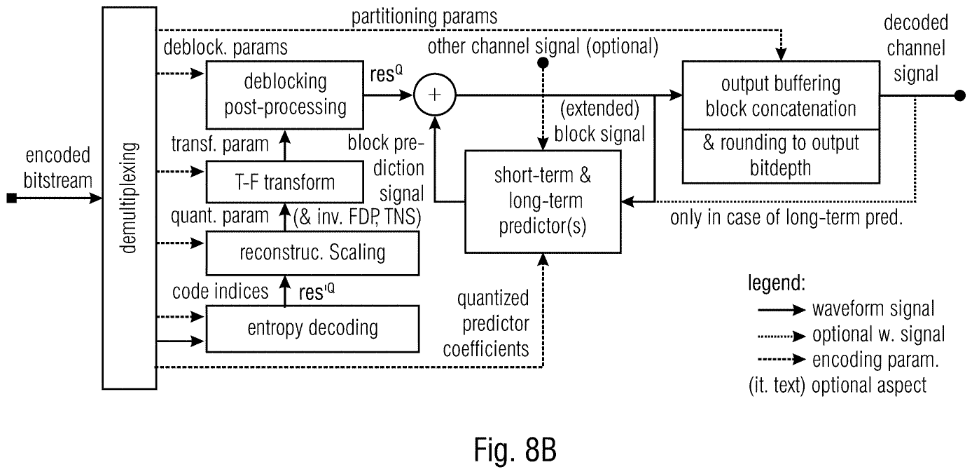

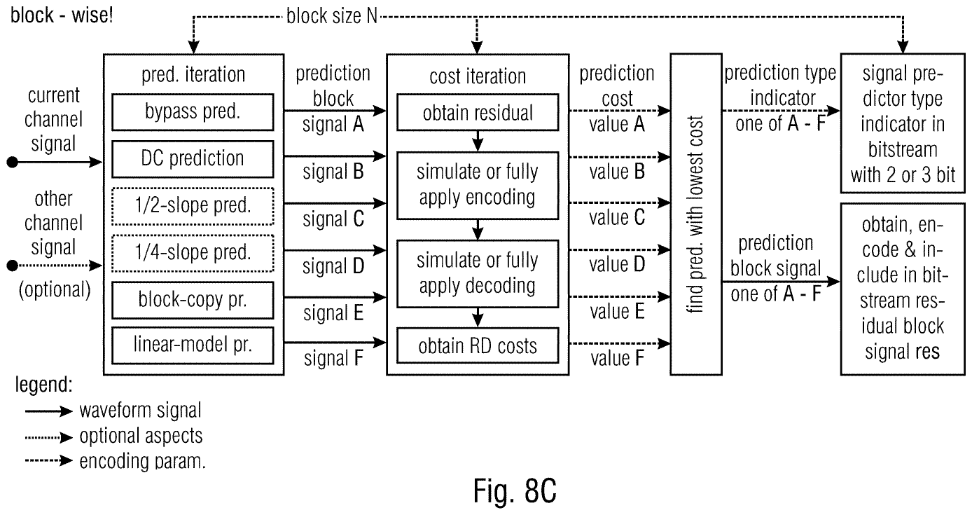

FIG. 8A shows a schematic view of an encoding procedure for encoding a digital time-varying signal. FIG. 8a illustrates how, according to the present description, the block diagram of FIG. 7 may be inventively extended, e.g., to enable lossy and, optionally, perceptually optimized compression. In the encoder shown in FIG. 8A, three further operational blocks may be present in a residual signal path:
a (optional) deblocking pre-process altering the to-be-transformed region of the residual signal in a way that, when reverting the alteration at the decoder side, may minimize subsequent blocking or ringing artefacts, e.g., caused by a following transform-domain quantization operation (see below); details of this inventive deblocking procedure are described in the next section below. It is noted that this deblocking procedure may employ one or more parameters, e.g., two parameters which, as will be discussed in the next section, may be signaled in different but, e.g., equivalent mathematical representations. Exemplarily signaled parameters of this coding step: 2 deblocking parameters (offset, slope/curvature) (or any other amount of deblocking parameters).
a forward transform applying, e.g., time-to-frequency (T-F) transformation using, as introduced earlier, a non-overlapping, e.g., non-windowed transform such as a DCT-2 or DST-2. More specifically, the non-overlapping condition means that the transformed region of the residual signal (i. e., the residual block) may not overlap with a past or a future transformed region of a residual signal, e.g., within the same channel or component. The non-windowed condition, on the other hand, means that no window function may need to be applied (e. g., multiplied) to the residual block data, e.g., before the transformation or after an inverse transformation, e.g., an implicit rectangular window may be assumed during both forward and inverse transformation. Exemplarily signaled parameters of this coding step: 1 transform type parameter (DCT-2/4 or DST-2/7).
a (optional) quantization process, enabling re-quantization of the transformed residual samples, e.g., remapping of the transform coefficient values to a smaller set of quantization indices, e.g., so as to achieve a bit-rate reduction during entropy coding and transmission. Such a quantizer may be, e.g., a scalar linear or nonlinear quantizer, e.g., with a quantization step-size, or a vector quantizer. Moreover, for example, additive (encoder-only) or subtractive dithering may be used in the quantization. Exemplarily signaled parameter of this coding step: block-wise quantization parameter (QP or delta-QP).

FIG. 8B shows an example of a decoding procedure for decoding a digital time-varying signal, e.g., a digital time-varying signal encoded by the encoding procedure shown in FIG. 8A.

A corresponding decoder, illustrated in FIG. 8B, contains three equivalent operational blocks in reverse signal processing order. Specifically, the (e.g., optional) quantization block is complemented by a reconstructive scaling (e.g., also called “inverse quantization”) block, e.g., controlled by a signaled block QP, a time-frequency (T-F) transform on the encoder side is undone by a frequency-time (F-T) transform (also referred to as “inverse transform” or “re-transform”), e.g., parameterized by a signaled transform type indicator, and a deblocking post-processor reverts the encoder-side deblocking pre-processing operation.

Regarding the choice of short-term, long-term, or cross-channel predictor applied on the channel before (in the encoder) resp. after (in the decoder) the deblocking processing, it is noted that, in the present invention, the encoder may obtain, e.g., depending on e. g. rate-distortion (RD) optimized search(es), a “most suitable” prediction signal to be applied in the coding of a given channel signal block of length, or size, N. In order to be able to obtain and apply the same prediction signal on the decoder side, the choice of prediction type may be signaled, e.g., on a block basis, in the bitstream via a, e. g., a 2-bit or 3-bit predictor index (e.g., depending on N, see below). For example, such an index may convey that, in addition to (e.g., cascaded with) the LPC based short-term predictor known from, e. g., the lossless codec of [1], exactly one out of a set of predictors supported for N (e.g., a set of allowed predictors may vary between different block sizes) is to be applied for the given block in both encoder and decoder. The inventive codec may provide, in addition to said LPC predictor, one or more of the following predictors (e.g., prediction modes), implementational and mathematical details of each of which are provided on the following pages:
a direct current (DC) predictor, called “mean predictor” hereafter, e.g., calculating in fixed-point arithmetic the average of the last K samples (e.g., with a pre-determined value of K, a signaled value of K, or a value of K derivable from already decoded samples) before the start (1^{st} sample) of the current block. Exemplary signaled parameter of this predictor (optional): k used in averaging (e. g., 0, 1 . . . , 7, or larger), or k is fixed
a bypass (i. e., disabled) predictor, e.g., which effectively turns off prediction, e. g., by zeroing the prediction signal; clearly, this predictor type may not need further parameters to be signaled.
a half-slope (straight-line) predictor, e.g., calculating as prediction signal a constantly increasing or decreasing straight line, e.g., whose slope is determined from the last few samples before the start of the current block (e.g., and/or based on signaling). The half term means that the calculated slope is weighted by ½ (however, different weight values or weighting may be possible). Signaled parameter of this predictor. E.g., none, the slope may be derived from past decoded samples
a quarter-slope (straight-line) predictor, e.g., calculating a straight line, e.g., from the last few samples (e.g., a pre-determined amount and/or signaled amount of samples) before the current block, as above. Unlike the half-slope predictor, the slope may be scaled by ¼. Signaled parameter of this predictor. e.g., none, the slope may be derived from past decoded samples
a block-copy (e.g., long-term) predictor, e.g., creating the prediction signal by copying a size-N part of past decoded signal parts, e.g., of the given channel and, optionally, scaling and/or filtering it. Exemplary signaled parameters of this predictor. copy offset, (optional) weight and/or filtering parameters
a cross-channel linear model predictor, e.g., calculating a least-squares optimized linear fit of the current block signal, e.g., from collocated samples of at least one other signal channel (e.g., possibly including, in both current and other channel(s), e.g., past samples or previously coded samples before the current block). Exemplary ignaled parameters of this predictor: one or more quantized linear model parameters, e.g., including offset parameter.

Advantageously, for one or more predictors (or prediction modes) such as the half-slope and/or quarter-slope predictors may not be allowed in large blocks, e. g., when N>64, e.g., for certain block sizes or size ranges. In that case, for example, only four predictors (or any other combination of predictors or prediction modes) may be supported (or enabled), and their choice can be signaled using 2 instead of 3 bit (e.g., or only 1 bit in case of only two predictors being enabled). FIG. 8C summarizes this aspect and the encoder-side prediction selection process.

FIG. 8C shows a schematic view of an example for a set of prediction modes and a selection therefrom. In the example shown in FIG. 8c, six prediction modes (or predictors) are available in form of bypass prediction, DC prediction, half-slope prediction, quarter-slope prediction, block-copy prediction, and linear-model prediction, wherein, optionally, half-slope prediction, quarter-slope prediction may be restricted to properties of the current block to be decoded (e.g., a size of the block and/or a position of the block relative to random access points). The encoder 10 may be configured to perform simulations or tests with one or more (e.g., all) prediction modes (e.g., which may be restricted depending on the currently coded block, e.g., by the block size) and perform a selection on which mode to use for the actual encoding based on a measure (e.g., cost) such as a rate-distortion measure (e.g., select the mode with the best or most optimized rate-distortion). The encoder 10 may subsequently signal a type indicator (e.g., indicating the selected prediction modes, e.g., using one, two, or three bits, depending on an optional restriction for the prediction modes) and an encoded version of the residual signal (e.g., residual signal 80).

For example, let x[M+1], . . . , x[M+N] denote the samples to be coded on the current block (e.g., with sample x having each a value an original domain 26 or time domain, e.g., with N denoting a length or sample amount of the current block, e.g., temporal block 140, e.g., with M indicating an amount of previously decoded samples, e.g., of the sample channel, e.g., of the entire time-varying signal 92 or a subset thereof). Let y[1], . . . , y[M] denote the already reconstructed samples (e.g., in the original domain 26), which are located before the current samples in a temporal way (e.g., previously coded samples). In one embodiment of this invention, the following set of prediction modes (but any other set of prediction modes may be used instead and the prediction modes themselves may be realized differently), meaning methods to generate a prediction signal pred[1], . . . , pred[N] for the samples x[M+1], . . . , x[M+N] out of some of the samples of y[1], . . . , y[M] may be supported (e.g., based on a linear combination such as a subtraction).
A DC- or mean-prediction mode. Here, for a fixed integer K≤M, e.g., with K being an integral power of 2, K=2 k, one may put

pred^{DC}[i]=(y[M]+ . . . +y[M−K+1]+(1<<(k−1)>>k, 1≤i≤N.

The operators “<<” and “>>” may indicate a logical bit shift to the left or right, e.g., wherein one shift of bits to the left (“<<”) functionally equates to a multiplication of two and one shift of bits to the right (“>>”) functionally equates to (an approximation of) a division by two. The number k may, for example, be signaled, e.g., per block, per channel, per sequence or per other temporal unit, or may be fixed to for example k=0, k=1, k=2 or to k=4 (e.g., or any other integer). In one case, a maximum number for the value k may exist and be taken into account in the binarization and entropy coding of k. This maximum number may depend on, for example, the blocksize N where an increase of N corresponds to a non-decrease of the maximum number. In another case, the number k may be fixed to a specific value (e.g., pre-determined value) per block-size N. Here, in one case, the fixed numbers may be such that an increase of N corresponds to a non-decrease of the maximum numbers.
A half-slope prediction mode generating the prediction samples pred^{hs}[i], 1≤i≤N. Here, first, the slope m between y_{M} and y_{M-1} may be computed as

m=y[M]−y[M−1]. (1)

However, it is found that a straight-line prediction with slope m to generate a prediction signal may typically yield prediction signals with too large input values, in particular at sample locations i far away from sample position 1. Thus, it is proposed to optionally scale down the slope, e.g., by the factor 0.5 and to thus put

mₕₛ:=(m+1)>>1

and then define

pred^{hs}[i]:=y[M]+i·mₕₛ, 1≤i≤N.

The half-slope may further define an offset or bias.
A quarter-slope prediction mode may genere the prediction samples pred^{qs}[i], 1≤i≤N in a similar way as for the half-slope mode, again with the reasoning of optionally scaling down the full slope. Thus, if the slope m may be defined as in (1) above, one may put

m_{qs}:=(m+2)>>2

and

pred^{qs}[i]:=y[M]+i·m_{qs}, 1≤i≤N.
A prediction mode which bypasses the prediction, and generates the zero-prediction signal may be defined as follows:

pred^{zero}[i]:=0, 1≤i≤N.
A prediction method by which, for example, based on one or more temporal offsets t₁, . . . , tₖ (e.g., with k indicating an amount of predictors or blocks to be used to generat prediction signal, e.g., k=2 for generating a prediction signal using two previously coded temporal blocks, e.g., temporal offsets 248₁ and/or 248₂) that may be, e.g., signalled in the data-stream, a temporal-offset prediction signal pred^{TO} may be generated out of the reconstructed samples

[y[M−N−t₁+1], y[M−N−t₁+2], . . . , y[M−N−t₁+N]],

:

[y[M−N−tₖ+1], y[M−N−tₖ+2], . . . , y[M−N−tₖ+N]],

possibly by applying multiple signal processing operations to these sets of reconstructed samples, for example a filtering operation. In one possible case, only one offset t₁ (e.g., with k=1) is signalled and the prediction is generated as

pred^{TO}[i]=y[M−N−t₁+i], 1≤i≤N.

In another possible case, two offsets t₁, t₂ (e.g., k=2) are signalled and the prediction is generated as

pred^{TO}[i]=(y[M−N−t₁+i]+y[M−N−t₂+i]+1)>>2, 1≤i≤N.

In possible cases, the temporal offsets may also have non-integral values, for example a value-range in a half-pel resolution (or other fractions of a sample length). Here, for a temporal offset t+½, interpolation filtering operations may be to be applied, e.g., in order to generate interpolated reconstructed samples y[M−N−t+1/2+i].
For the case that the whole signal contains multiple channels (e.g., the sample shown in FIG. 1 has 32 channels), where the samples x[i] (e.g., samples to be coded of a first channel) and y[i] (e.g., samples already coded of the first channel) belong to one of these channels and where by y^{c}[i], sample values shall be denoted that belong to a channel c which is different (e.g., samples of a second channel that is different from the first channel) from the channel to which the samples y[i], x[i] belong:
   A prediction method may be used by which, based on one or more channel indices c₁, . . . , c_{L} and temporal offsets t₁, . . . , t_{L} which, together with the (e.g., predetermined or signaled) value L, may be signalled in the data-stream, and based on (e.g., optionally signaled) values λ₁, . . . , λ_{L}, b which might either be signalled in the data stream or derived out of already reconstructed samples, the prediction signal may, for example, be generated as

$${pred}^{Ch} [ i ] = {\sum }_{k = 1}^{L} {λ}_{k} \cdot {y}^{{c}_{k}} [ M - {t}_{k} + i ] + b , 1 \leq i \leq N .$$

Here y^{c}^{ₖ}[M−tₖ+i] denotes a reconstructed sample value of channel cₖ at position M−tₖ+i. For this prediction mode, it may be required that the reconstructed sample values in the channels cₖ have already been coded respectively decoded up to the time instance M−tₖ+N.

In one embodiment, it might be the case that the prediction methods to generate the prediction signals pred^{hs} and pred^{qs} are not supported (e.g., not enabled) for large block-sizes. This is due to the fact, for example, that generating a prediction signal that arises by generating a line with some slope might yield extremely large or small sample values very far away from the block boundary where the line started and might thus not yield a suitable prediction. In another embodiment, a slope μ shall be explicitly signalled, for example, either as one option out of some predefined set M of allowed slope values (e.g., as an index in a look-up table) or in a specified binarization. Then, a prediction of the form

pred^{μ}[i]=y[M]+i·μ, 1≤i≤N.

shall be supported. However, a slope may also be determined based on already coded samples for large blocks, wherein, as an option, a parameter may be signaled to modify (e.g., decrease) the determined slope.

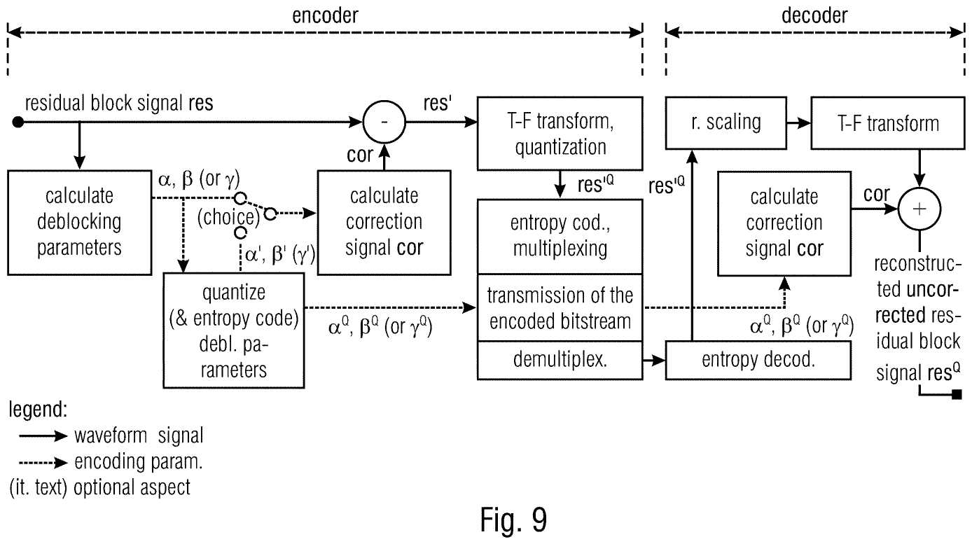

It shall be emphasized that the particular type of predictor chosen from the inventive set of six (or, for some N, four) types, as in FIG. 8C, may be applied in addition to the prior-art sample-by-sample LPC (linear predictive coding, e.g., in case of audio coding) based short-term predictor, whose parameters (filter order and quantized coefficients) may be determined independently. In other words, the short-term LPC predictor may be applied on the block residual signal of said predictor which is chosen out of the inventive set, i. e., after the latter prediction has been conducted in the encoder. This implies that, in the decoder, the LPC “synthesis” prediction may be, for example, performed before adding said prediction signal chosen out of the inventive set. In the case of lossless coding of the given block, e. g., as signaled via QP=0, the process may be straightforward since the quantization, transform, and deblocking steps may be typically bypassed and disallowed. During lossy coding, e. g., as indicated by QP>0, the short-term LPC “synthesis” prediction may operate, for example, on quantized, and possibly transformed and deblocked, sample values and, thereby, may enable spectral noise shaping (SNS), for example, by filtering the reconstructed residual samples and the quantization error included therein. FIG. 9 illustrates an example of a detailed operation of this coding scenario in a block diagram. The LPC prediction may be a bypass prediction, e.g., its filter order may be 0.

FIG. 9 shows an example of an encoder and decoder using LPC prediction. Any encoder and decoder disclosed herein may comprise any feature disclosed with reference to FIG. 9.

Regarding the choice of the transform type applied for a given (residual) signal block, the following aspects shall be noted. First, not all four transform types mentioned (i. e. DCT-2, DCT-4, DST-2, DST-7) may be necessarily allowed at all block sizes. Specifically, for example, the DST-7 transformation may be disabled for large block sizes N and, for example, either the signalling of a transform type index (e.g., for a look-up table of transform types or transform functions) may be adjusted accordingly for said N or, for example, the DST-7 may be replaced by a DST-4 kernel (or other kernels) during transformation. Second, as with prediction, the different transformation variants may, for example, be evaluated, e.g. in an RD optimization framework, during block encoding, and, for example, the “best” transform type selected, and signalled, e.g., with a sufficient number of bits (here, 2 bit for 3-4 choices) according to or based on, for example, the results of this RD evaluation.

It is noted that the identity transform (e.g., a factual absence of any forward or inverse transform) may be included as an option in a set of allowed transform type parameters that can be signaled. In that case, the (optional) coefficient quantizer may operate in the time instead of frequency domain. Analogously, it may be beneficial to support, for example, the signaling of both “zero” offset and/or “zero” slope or curvature as deblocking parameters, as a means to disable or bypass the deblocking feature.

To conclude this section, it is noted that an additional, optional frequency-domain prediction (FDP) filtering may be used, for example, between the quantization and (forward or inverse) transform steps in order to allow for sophisticated perceptual optimization of the waveform compression process [2], as indicated in FIG. 8A (see between quantization and T-F transform) and 8b (see between reconstruc. Scaling and F-T transform). Such frequency-domain prediction, which may be typically realized through pre- and post-filtering, may be used, for example, in audio coding. For example, such frequency-domain prediction may operate in an open-loop fashion (with FIR, finite impulse response, filtering prior to quantization on the encoder side and corresponding IIR, infinite impulse response, filtering after quantization on the decoder side) and, as such, may allow for temporal shaping of the quantization distortion. For this reason, the process is also called temporal noise shaping (TNS), in analogy to the spectral noise shaping (SNS) which may be realized, for example, by way of the LPC based time-domain prediction filtering. Due to an input signal dependence (e.g., in the TNS filter coefficients) of the frequency domain predictor, a combination of time-frequency transformation and TNS is sometimes referred to as a temporally signal adaptive transform, and, for example, by realizing that LPC based SNS is input dependent (in the LPC coefficients) as well, one can argue that TNS enhanced time-frequency transformation with LPC based SNS may represent a spectro-temporally signal adaptive transform. Such enhanced transforms are perfectly suited for perceptual coding.

### Detailed Description of Aspect 2: Deblocking

It is noted that the aspect 1 (“architecture”) described above is not an alternative of the aspect (“deblocking”) described herein. Instead, both aspects can be applied in isolation as well as in any combination.

FIG. 8 illustrates an example of the encoder- and decoder-side operation of the inventive parameter guided deblocking pre- and post-processing. A “forward” (e.g., transformation from time domain to frequency domain) pre-processor may modify the input block or, in an advantageous embodiment, residual block signal resᵢ (e.g., residual signal 80) by subtracting a result of a so-called corrective function corᵢ, for example, evaluated at the individual sample locations i of said residual block signal res. The intention (or a target to approach) here is to, among several possible objectives, reach zero crossing (e.g., reduce a chance of a value to cross a level of zero) of a resulting corrected residual block signal res′, e.g., at both the starting and the ending samples of the block region. Such “tapering” of the corrected residual waveform towards zero at both block boundaries may reduce spectral leakage during a following time-frequency transformation (or, in other words, increases spectral compaction) and, thus, may significantly reduce blocking and ringing artefacts when, for example, the transform coefficients (e.g., frequency samples) are requantized. Depending on block sample characteristics, an alternative (or additional) intention of said correction may be to minimize, instead of the above-noted discontinuities at the block boundaries, an overall tilt (e.g., a bias or increase towards higher frequencies) in res, where said tilt can, e. g., be determined by linear regression (linear-model) analysis [3].

At the decoder side, an “inverse” (e.g., transformation from frequency domain to time domain) of a deblocking pre-processor, e.g., the corresponding post-processor, undoes the above-described modification by adding the (identical) result of the corrective function corᵢ, e.g., again evaluated at the same sample locations i, e.g., to the quantized and reconstructed, previously corrected residual block signal res′^{Q}. To be specific, the cor signal used at the encoder side to obtain res' may be identical to the cor signal used during decoding to recover, from res′^{Q}, the reconstructed uncorrected residual block signal rese, which can now, for example, be subjected to inverse transformation (and optionally inverse TNS filtering) and inverse prediction. In order for this requirement to be feasible, the parameters of the corrective function cor may need to be signaled (e.g., coded and transmitted) from the encoder to the decoder as follows (but not limited thereto).

The decoder may be configured to decode one or more deblocking parameters from the data stream, perform deblocking post-processing (e.g., using a deblocking function) by modifying the time-domain prediction residual signal using the one or more deblocking parameters to obtain a modified time-domain prediction residual signal, perform the correcting the prediction signal using the modified time-domain prediction residual signal. The deblocking may be performed using a (e.g., corrective) deblocking function (e.g., a blocking-and-ringing-artefact-reducing function), which may have different shapes and parametrizations.

Let cor, for a block b (e.g., transform-coded temporal block), be fully described by one of the following functions with two parameters:
a linear function, for example, with offset parameter α and slope parameter β as in the discussion in [3]. In other words, the underlying model of such deblocking function may be (or be based on) a simple linear model, characterized by a linearly increasing or decreasing value progression, e.g., between its boundary indices at i=0 and i=N (with N being the block size): corᵢ=α+β·2·i with 0≤i<N
a trigonometric function, for example, with offset parameter α and curvature parameter γ, where said γ may control a maximum amplitude of, for example, a half-cosine angular function, e.g., between 0 and π. In this variant, the underlying model isn't linear but, for example, sinusoidal, characterized by a progression of its values between i=0 and i=N which is smoother and which may exhibit less pronounced slopes (1st-order derivative) at the block boundaries:

$${cor}_{i} = α + γ \cdot cos ( \frac{π}{N} \cdot i ) \cdot N$$

with 0≤i<N.

Four aspects regarding the above corrective functions are worth noting. First, in both variants of the function, the multiplication-by-i term, ·i, (e.g., sample position as functional parameter) may be replaced by a temporally shifted version thereof, e.g., ·(i+0.5) (or any other integer or rational number or a number between −1 and 1), for example, to obtain a temporally symmetric function within the processed block b. Second, both functions may be parametrized in different ways such as by the parameters described above and/or by their start and end values in b, e.g., by their boundary anchor values which are the result of evaluating the respective function at i=0 and i=N (or N−1). In other words, signaling, for each block b, said two anchor values to the decoder instead of α and β or α and γ may be, in the absence of quantization or precision differences, mathematically equivalent since the latter two parameters can be determined from the anchor values (e.g., a and B may be determined based on values of the residual signal at a first and last sample of the block, i.e., for i=0 and i=N−1). Third, to limit the number of bits that may be required for transmission of the deblocking parameters within the bitstream, especially when b is of small size, the one or more function parameters such as a and B or a and y (or, equivalently as noted, anchor values or similar parameters that allow defining the deblocking function) may be quantized as well. For example, they may be quantized more finely than the transform coefficients, e.g., using a smaller step size or QP, and/or with a scalar linear quantizer. In general, a good trade-off between bit consumption of the quantized deblocking parameters and effectivity of the deblocking pre/post-processing—e.g., a low deblocking cost—may be desirable. In consequence, this implies that, given high-cost cases, it may be useful to signal deblocking parameters only, for example, when a further bitstream element, e. g., a 1-bit flag, indicates that such parameters are present for block b.

FIG. 10 shows an example of a decoded residual signal without deblocking (upper plot) and with deblocking (lower plot). The residual signal was re-transformed using as transform DST-II and with a block size of 640. As can be seen in the upper plot, the signal shows occasional deviation (e.g., spikes) from its original shape of a wave function. However, after deblocking, as can be seen in the lower plot, the signal exhibits a smooth waveform shape. FIG. 10 illustrates the effect of the guided deblocking on an audio signal.

Fourth, when parametrizing the corrective deblocking function (e.g., a blocking-and-ringing-artefact-reducing function) by said two boundary anchor values (e.g., deblocking parameters), it may not be necessary to explicitly signal (e.g., transmit) the starting (e.g., left) anchor parameter (e.g., it may be sufficient to transmit the ending anchor parameter, but not the starting anchor parameter). Instead, it often suffices to implicitly signal (e.g., derive) said starting anchor value (e.g., a further deblocking parameter, e.g., a derived deblocking parameter) via previously decoded signal information (e.g., wherein a decoder is configured to determine the starting anchor value based on one or more already decoded sample values, e.g., by default and/or based on an indicator in the bit stream, e.g., an indicator at the start of the bit stream or portion thereof such as a start of a temporal block 30) at i<0 (e.g., previously decoded samples, e.g., immediately preceding samples, e.g., of the same channel) since the starting anchor value (e.g., deblocking parameter) evaluates the corrective deblocking function at i=0 (e.g., a first sample of a temporal block 140 being indexed by a sample index i=0), i.e., in the direct vicinity of the ending part of the already decoded signal region (e.g., based on sample values of one or more samples immediately preceding a currently coded block, e.g., of the same channel). Specifically, said starting anchor value at i=0 can be derived using linear regressive extrapolation (or any other form of extrapolation, e.g., using other statistical values such as an average) from the four locations −5<i<0 (e.g., or any other number such as two, three, five, or more locations or samples) and on a “virtual residual boundary signal” at these four locations, which can be constructed, on both encoder and decoder side, as a difference (e.g., sample-wise difference) between the reconstructed signal samples at (e.g., the four locations at sample indexes −5<i<0), and an extension (e.g., based on an extrapolation or extension of the prediction signal to extend more samples) of the prediction signal for the current block towards, −5<i<0, assuming that i<0 points to available signal samples (otherwise, the starting anchor value may be set to 0). In other words, only the ending (e.g., right) anchor parameter must (or can) be signaled, for example, in a quantized form (e.g., quantized as described herein for two anchor points, e.g., with smaller quantization steps than the transform coefficients), while the starting (e.g., left) anchor value may be derived from other information in the bitstream (e.g., based on already coded samples), thereby saving side-information bits required for the deblocking procedure.

In the following, embodiments related to “Deblocking-En/Decoder Embodiment” are discussed.

### Deblocking-Encoder Embodiment

In each residual transform block b of each channel in the biomedical, seismic, or acoustic signal (where the term acoustic may include both human generated speech or music material as well as non-human input such as sonar recordings), the encoder may determine and quantize the one or two deblocking parameters (however, the following example will be described with two parameters), using the residual block signal res, prior to transforming res′, as follows:

1 (optional). When res is not low-pass enough-which can be determined, for example, by high-pass filtering res, calculating a variance varₕₚ of the high-pass block signal, and comparing the ratio of varₕₚ and varᵣₑₛ (the variance of res itself) against a threshold T—the two deblocking parameters shall exemplarily represent offset α and slope β. The α and β parameters, as outlined previously, can be obtained, for example, via simple linear regression [3], with μᵢₓ and μᵣₑₛ denoting the mean of i and res, respectively, in block b:

β=sumᵢ[(i−μᵢₓ)·(resᵢ−μᵣₑₛ)]/sumᵢ[(i−μᵢₓ)²],α=μᵣₑₛ−β·μᵢₓ with index 0≤i<N. (1)

It is noted that term i−μᵢₓ can be known a priori, as it only depends on a block size N. Such line fitting derived parameters may minimize the overall DC offset and temporal tilt in res inside block b, thereby reducing, for example, the magnitudes of the lowest-frequency transform coefficients resulting from transformation of res′.

2. When res is low-pass enough (e.g., step 1 has not been executed or the comparison against a threshold in step 1 failed, e. g. by having evaluated to false), the two deblocking parameters may represent two anchor points of res at the boundaries of block b. The values res_{L} and res_{R} of these two points are, for example, determined by averaging two consecutive values of res at each boundary (e.g., wherein the index indicates a position of a sample, wherein an index of zero indicates a first or leftmost position of block b):

res_{L}=0.5·(res₋₁+res₀), res_{R}=0.5·(res_{N-1}+res_{N}). (2)

It is noted that in the example above, the values res₋₁ and res_{N} are actually located outside of b, thus, any block prediction signal used in the determination of res may need to be extended by an extra sample on each side of b in order for res (e.g., a difference between input signal and prediction signal) to include index −1 and index N. In cases where this is not feasible or desirable or the employed transform is not a DST-∥, a simpler assignment res_{L}=res₀, res_{R}=res_{N-1} may be utilized instead (e.g., for one or both anchor points). From res_{L} and res_{R}, the offset and slope or, alternatively, curvature parameters can then be obtained, for example, as follows:

linear function (line fit): β=0.5·(res_{R}−res_{L})/{N when eqn. (2) is used, else N−1}, α=res_{L}

trigonometric function: γ=0.5·(res_{L}−res_{R})/{N when (2) is used, else N−1}, α=res_{L}−γN

It is noted that more accurate calculations of a may be devised especially in case of the above simple assignment res_{L}=res₀, res_{R}=res_{N-1}.

3. On very noisy residual block signals, deblocking via function cor may not provide merit. For example, such cases can be identified by measuring a zero-crossing rate [4] of corrected residual block signal using, for example, the following expression for res′ᵢ or res″ᵢ:

res′ᵢ=resᵢ−corᵢ(or, alternatively, res″ᵢ=resᵢ−μᵣₑₛ which can be calculated faster) for 0≤i<N.

If said zero-crossing rate [4] (or similar measures) lies above some further (e.g., pre-determined) threshold, α=β (or γ)=0 may be assumed and deblocking may, for example, be disabled, or bypassed, for example, by signaling “deblocking off” in a 1-bit flag for b.

4. When “deblocking off” is not signaled in step 3, but the values of a and B (or y) are near-zero, deblocking may optionally also be disabled, or bypassed, by signaling “deblocking off” in a 1-bit flag for b.

5. Otherwise (e.g., neither is res very noisy, nor are the deblocking parameters of b near-zero in magnitude), the two deblocking parameters α and β (or γ) obtained in steps 1-2 may optionally be quantized,

α^{Q}=round(α/(2·Δ), x^{Q}=round(x·N/Δ) with Δ: step-size, x: placeholder for β or γ, (3)

and “deblocking on” may be signaled in the 1-bit flag for b, for example, followed by the two quantized parameter values α^{Q} and β^{Q} (or γ^{Q}), using, for example, a lower bit depth per parameter than the input signal's bit depth.

6. The two deblocking parameters α and β (or γ) may be now used to construct (e.g., modify), for 0≤i<N, the cor function using which the subtractive deblocking pre-processing introduced earlier is performed, yielding corrected residual block signal res' which is time-frequency transformed and quantized.

### Deblocking-Decoder Embodiment

In the decoder, the (e.g., quantized) frequency-domain coefficients may be reconstructed and subjected to frequency-time (e.g., inverse) transformation, resulting in (e.g., quantized) previously corrected residual block signal res^{Q}. Further, reconstructions of a and B (or y) may be calculated from α^{Q} and β^{Q} (or γ^{Q}), for example, using the following equations:

α′=α^{Q}·2·Δ, x′=x^{Q}·Δ/N with Δ: step-size, x: placeholder for β or γ, (4)

from which may be derived, again for 0≤i<N, the cor function using which the additive deblocking post-processing described earlier may be performed. Said deblocking post-processing may represent the inverse of the encoder-side deblocking pre-processing. It is noted that, by employing the quantized α^{Q} and β^{Q} (or γ^{Q}) parameters also in the encoder-side construction of cor, used in the subtractive pre-processing step, the pre-processing and post-processing operations may cancel out perfectly. Hence, when deriving cor in the encoder, α, β, and γ may be replaced by α′, β′, and γ′, respectively.

### Introductory Remarks:

Above, different inventive embodiments and aspects are described, inter alia, in “Perceptual coding and decoding of biomedical, seismic, and related waveform signals”, in a chapter “Shortcoming of Traditional Transform Coding”, in a chapter “Conventional Solutions and Their Drawbacks”, in a chapter “Summary of the Inventive (De) coding Solution”, in a chapter “Detailed Description of Aspect 1: Architecture” and in a chapter “Detailed Description of Aspect 2: Deblocking”.

Also, further embodiments will be defined by the enclosed claims.

It should be noted that any embodiments as defined by the claims can be supplemented by any of the details (features and functionalities) described in the above mentioned chapters.

Also, the embodiments described in the above mentioned chapters can be used individually, and can also be supplemented by any of the features in another chapter, or by any feature included in the claims.

Also, it should be noted that individual aspects described herein can be used individually or in combination. Thus, details can be added to each of said individual aspects without adding details to another one of said aspects.

Moreover, features and functionalities disclosed herein relating to a method can also be used in an apparatus (configured to perform such functionality). Furthermore, any features and functionalities disclosed herein with respect to an apparatus can also be used in a corresponding method. In other words, the methods disclosed herein can be supplemented by any of the features and functionalities described with respect to the apparatuses.

Also, any of the features and functionalities described herein can be implemented in hardware or in software, or using a combination of hardware and software, as will be described in the section “implementation alternatives”.

### Implementation Alternatives:

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

The above described embodiments are merely illustrative for the principles of the present invention. It is understood that modifications and variations of the arrangements and the details described herein will be apparent to others skilled in the art. It is the intent, therefore, to be limited only by the scope of the impending patent claims and not by the specific details presented by way of description and explanation of the embodiments herein.

### REFERENCES

[1] Y. Reznik, “Coding of Prediction Residual in MPEG-4 Standard for Lossless Audio Coding,” in Proc. IEEE Int. Conf. Acoustics, Speech, Signal Process. (ICASSP), Montreal, CA, May 2004.
[2] J. Herre, “Temporal Noise Shaping, Quantization and Coding Methods in Perceptual Audio Coding: A Tutorial Introduction,” Proc. AES 17^{th} Int. Conf. High Quality Audio Coding, 1998.
[3] Wikipedia, “Simple linear regression,” https://en.wikipedia.org/wiki/Simple linear regression
[4] Wikipedia, “Zero-crossing rate,” https://en.wikipedia.org/wiki/Zero-crossing_rate, December 2023.

1. Decoder for decoding a digital time-varying signal from a data stream, configured to
decode the digital time-varying signal from the data stream in non-overlapping temporal blocks by decoding each of transform-coded temporal blocks of the non-overlapping temporal blocks of the digital time-varying signal by
predicting the respective transform-coded temporal block using a selected prediction mode out of a set of prediction modes to acquire a prediction signal,
decoding coefficients from the data stream, the coefficients representing a prediction residual signal of the respective transform-coded temporal block in a transform domain,
subjecting the coefficients to a predetermined re-transformation from the transform domain to time domain to acquire a time-domain prediction residual signal representing a prediction residual signal of the respective transform-coded temporal block in a time domain, and
correcting the prediction signal using the time-domain prediction residual signal,
wherein the predetermined re-transformation is a non-overlapping transform.

2. Decoder of claim 1, wherein the predetermined re-transformation is an inverse discrete cosine transform or an inverse discrete sine transform.

3. Decoder of claim 1, wherein the predetermined re-transformation is representable by a matrix multiplication between a transform matrix and a first vector whose components are formed by the coefficients, wherein an output vector resulting from the matrix multiplication comprises as many components as samples comprised by the time-domain prediction residual signal.

4. Decoder of claim 1, wherein the transform domain results from the time domain according to a predetermined transformation, wherein the decoder is configured to select the predetermined transformation out of a set of transformations, wherein the re-transformation reverses the predetermined transformation.

5. Decoder of claim 4, configured to select the set of transformations out of a superset of transformations depending on one or more of
a length of the respective transform-coded temporal block,
the selected prediction mode for the respective transform-coded temporal block.

6. Decoder of claim 4, wherein the set of transformations comprises one or more of
one or more discrete cosine transforms,
one or more discrete sine transforms, and
an identity transform.

7. Decoder of claim 6, configured to skip the subjecting the coefficients to the predetermined re-transformation if the predetermined transformation is the identity transform.

8. Decoder of claim 1, wherein the transform domain results from the time domain according to a predetermined transformation, wherein the predetermined transformation and the predetermined re-transformation are windowing free.

9. Decoder of claim 1, wherein the transform domain results from the time domain according to a predetermined transformation, wherein the predetermined transformation is a spectrally decomposing transformation.

10. Decoder of claim 1, wherein a sample rate of the digital time-varying signal is above, or equal to, a Nyquist rate of the transform domain.

11. Decoder of claim 1, wherein, for each transform-coded temporal block, a number of the coefficients coincides with a number of samples of the respective transform-coded temporal block.

12. Decoder of claim 1, wherein the time-domain prediction residual signal results from the subjecting the coefficients of the respective transform-coded temporal block to the predetermined re-transformation in a manner independent from a prediction residual signal of temporally adjacent temporal blocks, preceding and following the respective transform-coded temporal block

13. Decoder of claim 1, wherein the transform domain is a critically sampled transform domain.

14. Decoder of claim 1, wherein basis functions of the predetermined re-transformation are of a length coinciding with a length of the respective transform-coded temporal block.

15. Decoder of claim 1, wherein the set of prediction modes comprises one or more of
a DC prediction mode according to which the prediction signal of the respective transform-coded temporal block is determined to be a constant function with a determination of a constant of the constant function based on predetermined already decoded samples preceding the respective transform-coded temporal block,
one or more linear prediction modes according to which the prediction signal of the respective transform-coded temporal block is determined to be a linear function with a determination of at least one of a slope and an offset of the linear function based on predetermined already decoded samples preceding the respective transform-coded temporal block,
a block-copy prediction mode according to which the prediction signal of the respective transform-coded temporal block is predicted based on one or more reference block portions of already decoded samples preceding the respective transform-coded temporal block offset relative to the respective transform-coded temporal block at a position signalled for the respective transform-coded temporal block in the data stream,
a cross-channel prediction mode according to which the prediction signal of the respective transform-coded temporal block is predicted based on one or more reference coded channels out of coded channels which represent a multi-channel signal coded into the data stream and to be decoded from the data stream by the decoder, and one of which is represented by the digital time-varying signal, and
a bypass prediction mode according to which the prediction signal of the respective transform-coded temporal block is set to zero,

16. Decoder of claim 1,
wherein the digital time-varying signal is acquired by at least one of Electrocardiogra Electroencephalography, Electromyography or seismic measurement, and/or
wherein the digital time-varying signal is a bio-physiological waveform data such as an electroencephalography signal, an electrocardiogram, or an electromyography signal, or is a seismic waveform signal.

17. Decoder of claim 1, configured to
configured to support different lengths of the transform-coded temporal blocks and set a length of the transform-coded temporal blocks according to a length parameter in the data stream.

18. Decoder of claim 1,
configured to support different lengths of the transform-coded temporal blocks and switch between the different lengths of the transform-coded temporal blocks at predetermined borders between consecutive temporal blocks according to a length parameter in the data stream.

19. Decoder of claim 1, configured to
decode one or more deblocking parameters from the datastream,
perform deblocking post-processing by modifying the time-domain prediction residual signal using the one or more deblocking parameters to acquire a modified time-domain prediction residual signal,
perform the correcting the prediction signal using the modified time-domain prediction residual signal.

20. Decoder of claim 19, wherein the one or more deblocking parameters define a linear function.

21. Decoder of claim 19, wherein the one or more deblocking parameters define a trigonometric half-wave function parametrized by a half-wave offset and an half-wave amplitude.

22. Decoder of claim 19, wherein the one or more deblocking parameters define a blocking-and-ringing-artefact-reducing function and the decoder is configured to modify the time-domain prediction residual signal using the one or more deblocking parameters to acquire the modified the time-domain prediction residual signal by linearly combining the blocking-and-ringing-artefact-reducing function and the time-domain signal.

23. Decoder of claim 19, wherein the one or more deblocking parameters comprise a gating flag which, if set, indicates that the deblocking post-processing is active and that the one or more deblocking parameters comprise one or more function parameters defining a blocking-and-ringing-artefact-reducing function ought to be linearly combined with the time-domain prediction residual signal to acquire the modified time-domain prediction residual signal, and, if not set, indicates that the deblocking post-processing is inactive, the one or more deblocking parameters only comprise the gating flag, and the modified time-domain prediction residual signal equals the time-domain prediction residual signal.

24. Decoder of claim 19, configured to
determine a further deblocking parameter based on the prediction signal of the respective transform-coded temporal block and one or more already coded samples of the digital time-varying signal,
perform the deblocking post-processing by modifying the time-domain prediction residual signal using the one or more deblocking parameters and the further deblocking parameter to acquire the modified time-domain prediction residual signal.

25. Decoder of claim 24, configured to
determine an extension of the prediction signal of the digital time-varying signal,
combine the extension of the prediction signal and the one or more already coded samples of the digital time-varying signal in order to acquire a modified version of the one or more already coded samples, and
determine the further deblocking parameter based on an extrapolation of the modified version of the one or more already coded samples.

26. Decoder of claim 24, configured to
determine an extrapolation of a plurality of already coded samples that precede the respective transform coded temporal block,
determine the further deblocking parameter based on the extrapolation of the plurality of already coded samples and the prediction signal.

27. Decoder of claim 24,
wherein the further deblocking parameter and the one or more deblocking parameters define a linear function.

28. Decoder of claim 24,
wherein the further deblocking parameter and the one or more deblocking parameters define a trigonometric half-wave function parametrized by a half-wave offset and an half-wave amplitude.

29. Decoder of claim 24,
wherein the one or more deblocking parameters define a blocking-and-ringing-artefact-reducing function and the decoder is configured to modify the time-domain prediction residual signal using the one or more deblocking parameters to obtain the modified the time-domain prediction residual signal by linearly combining the blocking-and-ringing-artefact-reducing function and the time-domain signal,
wherein the blocking-and-ringing-artefact-reducing function is defined by the one or more deblocking parameters and by the further deblocking parameter.

30. Decoder of claim 24, wherein the further deblocking parameter is determined to minimize a value of a first sample of the modified time-domain prediction residual signal.

31. Decoder of claim 24, wherein samples values of zero are assumed for the already coded samples of the digital time-varying signal, if no already coded samples of the digital time-varying signal are available.

32. Encoder for encoding a digital time-varying signal into a data stream, configured to
encode the digital time-varying signal into the data stream in non-overlapping temporal blocks by encoding each of transform-coded temporal blocks of the non-overlapping temporal blocks of the digital time-varying signal by
predicting the respective transform-coded temporal block using a selected prediction mode out of a set of prediction modes to acquire a prediction signal,
subjecting a time-domain prediction residual signal representing a prediction residual signal of the respective transform-coded temporal block in a time domain to a predetermined transformation from the time domain to a transform domain to acquire coefficients representing the prediction residual signal of the respective transform-coded temporal block in the transform domain, and
encoding the coefficients into the data stream so as to be used for correcting the prediction signal,
wherein the predetermined transformation is a non-overlapping transform.

33. Encoder of claim 32, wherein the predetermined transformation is a discrete cosine transform or a discrete sine transform.

34. Encoder of claim 32, wherein the predetermined transformation is representable by a matrix multiplication between a transform matrix and a first vector whose components are formed by samples comprised by the time-domain prediction residual signal, wherein an output vector resulting from the matrix multiplication comprises a many components as the coefficients.

35. Encoder of claim 32, wherein the encoder is configured to select the predetermined transformation out of a set of transformations.

36. Encoder of claim 35, configured to select the set of transformations out of a superset of transformations depending on one or more of
a length of the respective transform-coded temporal block,
the selected prediction mode for the respective transform-coded temporal block.

37. Encoder of claim 35, wherein the set of transformations comprises one or more of
one or more discrete cosine transforms,
one or more discrete sine transforms, and
an identity transform.

38. Encoder of claim 37, configured to skip the subjecting the time-domain prediction residual signal to the predetermined transformation if the predetermined transformation is the identity transform.

39. Encoder of claim 32, wherein the predetermined transformation is windowing free.

40. Encoder of claim 32, wherein the predetermined transformation is a spectrally decomposing transformation.

41. Encoder of claim 32, wherein a sample rate of the digital time-varying signal is above, or equal to, a Nyquist rate of the transform domain.

42. Encoder of claim 32, wherein, for each transform-coded temporal block, a number of the coefficients coincides with a number of samples of the respective transform-coded temporal block.

43. Encoder of claim 32, configured to subject the time-domain prediction residual signal to the predetermined transformation in a manner independent from a prediction residual signal of temporally adjacent temporal blocks, preceding and following the respective transform-coded temporal block

44. Encoder of claim 32, wherein the transform domain is a critically sampled transform domain.

45. Encoder of claim 32, wherein basis functions of the predetermined transformation are of a length coinciding with a length of the respective transform-coded temporal block.

46. Encoder of claim 32, wherein the set of prediction modes comprises one or more of a DC prediction mode according to which the prediction signal of the respective transform-coded temporal block is determined to be a constant function with a determination of a constant of the constant function based on predetermined already encoded samples preceding the respective transform-coded temporal block,
one or more linear prediction modes according to which the prediction signal of the respective transform-coded temporal block is determined to be a linear function with a determination of at least one of a slope and an offset of the linear function based on predetermined already encoded samples preceding the respective transform-coded temporal block,
a block-copy prediction mode according to which the prediction signal of the respective transform-coded temporal block is predicted based on one or more reference block portions of already encoded samples preceding the respective transform-coded temporal block offset relative to the respective transform-coded temporal block at a position signalled for the respective transform-coded temporal block in the data stream,
a cross-channel prediction mode according to which the prediction signal of the respective transform-coded temporal block is predicted based on one or more reference coded channels out of coded channels which represent a multi-channel signal to be coded into the data stream, and one of which is represented by the digital time-varying signal, and
a bypass prediction mode according to which the prediction signal of the respective transform-coded temporal block is set to zero,

47. Encoder of claim 32,
wherein the digital time-varying signal is acquired by at least one of Electrocardiogra Electroencephalography, Electromyography or seismic measurement, and/or
wherein the digital time-varying signal is a bio-physiological waveform data such as an electroencephalography signal, an electrocardiogram, or an electromyography signal, or is a seismic waveform signal.

48. Encoder of claim 32, configured to
configured to support different lengths of the transform-coded temporal blocks and to selectively set a length of the transform-coded temporal blocks in the data stream.

49. Encoder of claim 32, configured to
support different lengths of the transform-coded temporal blocks,
select and encode a length parameter in the data stream, wherein a switching between different lengths of the transform-coded temporal blocks is performed at predetermined borders between consecutive temporal blocks.

50. Encoder of claim 32, configured to:
perform a deblocking pre-processing by
determining one or more deblocking parameters,
modifying the time-domain prediction residual signal of the respective transform-coded temporal block using the one or more deblocking parameters to acquire a modified time-domain prediction residual signal,
subjecting the modified time-domain prediction residual signal to the predetermined transformation from the time domain to the transform domain to acquire coefficients, wherein the transformation is a non-overlapping transform.

51. Encoder of claim 50, wherein the one or more deblocking parameters define a linear function.

52. Encoder of claim 50, wherein the one or more deblocking parameters define a trigonometric half-wave function by way of a half-wave offset and an half-wave amplitude.

53. Encoder of claim 50, wherein the one or more deblocking parameters define a blocking-and-ringing-artefact-reducing function and the encoder is configured to modify the time-domain prediction residual signal using the one or more deblocking parameters by linearly combining the blocking-and-ringing-artefact-reducing function and the time-domain signal.

54. Encoder of claim 50, wherein the one or more deblocking parameters comprise a gating flag which, if set, indicates that the deblocking pre-processing is active and that the one or more deblocking parameters comprise one or more function parameters defining a blocking-and-ringing-artefact-reducing function ought to be linearly combined with the time-domain prediction residual signal to yield the modified time-domain prediction residual signal, and, if not set, indicates that the deblocking pre-processing is inactive, the one or more deblocking parameters only comprise the gating flag, and the modified prediction residual time-domain signal equals the time-domain prediction residual signal.

55. Encoder of claim 50, wherein the one or more deblocking parameters define a blocking-and-ringing-artefact-reducing function, and the encoder is configured to modify the time-domain prediction residual signal using the one or more deblocking parameters by linearly combining the blocking-and-ringing-artefact-reducing function and the time-domain prediction residual signal and determine the one or more deblocking parameters so that the linearly combining the blocking-and-ringing-artefact-reducing function and the time-domain prediction residual signal results
in the modified time-domain prediction residual signal getting zero at a leading and trailing end of the respective transform-coded temporal block, or getting closer to zero than a predetermined maximum distance, or
in the modified time-domain prediction residual signal getting a zero mean slope within respective transform-coded temporal block, or in a mean slope of the modified time-domain prediction residual signal getting closer to zero than a predetermined maximum deviation,

56. Encoder of claim 50, wherein the one or more deblocking parameters define a blocking-and-ringing-artefact-reducing function and wherein the encoder is configured to modify the time-domain prediction residual signal using the one or more deblocking parameters by linearly combining the blocking-and-ringing-artefact-reducing function and the time-domain prediction residual signal, and wherein the encoder is configured to Determine a statistical dispersion value of the time-domain prediction residual signal, If the statistical dispersion value falls into a value range being indicative of a smooth signal, determine the one or more deblocking parameters so that the linearly combining the blocking-and-ringing-artefact-reducing function and the time-domain prediction residual signal results
in the modified time-domain prediction residual signal getting zero at a leading and trailing end of the respective transform-coded temporal block, or getting closer to zero than a predetermined maximum distance,
If the statistical dispersion value falls into a value range being indicative of a non-smooth signal,
determine the one or more deblocking parameters so that the linearly combining the blocking-and-ringing-artefact-reducing function and the time-domain prediction residual signal results
in the modified time-domain prediction residual signal getting a zero mean slope within respective transform-coded temporal block, or in a mean slope of the modified time-domain prediction residual signal getting closer to zero than a predetermined maximum deviation.

57. Encoder of claim 50, configured to
Determine a noisiness measure of the time-domain signal,
If the noisiness measure falls into a value range being indicative of a noisy signal,
not set a gating flag comprised by the one or more deblocking parameters so as to indicate that the deblocking pre-processing is inactive so that the one or more deblocking parameters only comprise the gating flag, and the modified time-domain prediction residual signal equals the time-domain signal, or
set one or more function parameters which define a blocking-and-ringing-artefact-reducing function ought to be linearly combined with the time-domain prediction residual signal to acquire the modified time-domain prediction residual signal and are comprised by the one or more deblocking parameters so that the blocking-and-ringing-artefact-reducing function is zero so that that a deblocking is effectively disabled and
If the noisiness measure does not fall into the value range being indicative of a noisy signal, Determine the one or more function parameters so that so that the linearly combining the blocking-and-ringing-artefact-reducing function and the time-domain signal results
in the modified time-domain prediction residual signal getting zero at a leading and trailing end of the respective transform-coded temporal block, or getting closer to zero than a predetermined maximum distance, or
in the modified time-domain signal getting a zero mean slope within respective transform-coded temporal block, or in a mean slope of the modified time-domain prediction residual signal getting closer to zero than a predetermined maximum deviation,

58. Encoder of claim 50, configured to encode the one or more deblocking parameters in the data stream.

59. Encoder of claim 50, configured to
determine a further deblocking parameter based on the prediction signal of the respective transform-coded temporal block and one or more already coded samples of the digital time-varying signal,
perform the deblocking post-processing by modifying the time-domain prediction residual signal using the one or more deblocking parameters and the further deblocking parameter to acquire the modified time-domain prediction residual signal.

60. Encoder of claim 59, configured to
determine an extension of the prediction signal of the digital time-varying signal,
combine the extension of the prediction signal and the one or more already coded samples of the digital time-varying signal in order to acquire a modified version of the one or more already coded samples, and
determine the further deblocking parameter based on an extrapolation of the modified version of the one or more already coded samples.

61. Encoder of claim 59, configured to
determine an extrapolation of a plurality of already coded samples that precede the respective transform coded temporal block,
determine the further deblocking parameter based on the extrapolation of the plurality of already coded samples and the prediction signal.

62. Encoder of claim 59,
wherein the further deblocking parameter and the one or more deblocking parameters define a linear function.

63. Encoder of claim 59,
wherein the further deblocking parameter and the one or more deblocking parameters define a trigonometric half-wave function parametrized by a half-wave offset and an half-wave amplitude.

64. Encoder of claim 53,
wherein the encoder is configured to determine a further deblocking parameter based on the prediction signal of the respective transform-coded temporal block and one or more already coded samples of the digital time-varying signal,
wherein the encoder is configured to perform the deblocking post-processing by modifying the time-domain prediction residual signal using the one or more deblocking parameters and the further deblocking parameter to acquire the modified time-domain prediction residual signal,
wherein the blocking-and-ringing-artefact-reducing function is defined by the one or more deblocking parameters and by the further deblocking parameter.

65. Encoder of claim 59, wherein the further deblocking parameter is determined to minimize a value of a first sample of the modified time-domain prediction residual signal.

66. Encoder of claim 59, wherein samples values of zero are assumed for the already coded samples of the digital time-varying signal, if no already coded samples of the digital time-varying signal are available.

67. Method for decoding for decoding a digital time-varying signal from a data stream, the method comprising
decoding the digital time-varying signal from the data stream in non-overlapping temporal blocks by decoding each of transform-coded temporal blocks of the non-overlapping temporal blocks of the digital time-varying signal by
predicting the respective transform-coded temporal block using a selected prediction mode out of a set of prediction modes to acquire a prediction signal,
decoding coefficients from the data stream, the coefficients representing a prediction residual signal of the respective transform-coded temporal block in a transform domain,
subjecting the coefficients to a predetermined re-transformation from the transform domain to time domain to acquire a time-domain prediction residual signal representing a prediction residual signal of the respective transform-coded temporal block in a time domain, and
correcting the prediction signal using the time-domain prediction residual signal,
wherein the predetermined re-transformation is a non-overlapping transform.

68. Method for encoding a digital time-varying signal into a data stream, configured to
encode the digital time-varying signal into the data stream in non-overlapping temporal blocks by encoding each of transform-coded temporal blocks of the non-overlapping temporal blocks of the digital time-varying signal by
predicting the respective transform-coded temporal block using a selected prediction mode out of a set of prediction modes to acquire a prediction signal,
subjecting a time-domain prediction residual signal representing a prediction residual signal of the respective transform-coded temporal block in a time domain to a predetermined transformation from the time domain to a transform domain to acquire coefficients representing the prediction residual signal of the respective transform-coded temporal block in the transform domain, and
encoding the coefficients into the data stream so as to be used for correcting the prediction signal,
wherein the predetermined transformation is a non-overlapping transform.

69. Data stream encoded using the method according to claim 69.

70. A non-transitory digital storage medium having a computer program stored thereon to perform the method of claim 67 when said computer program is run by a computer.

71. A non-transitory digital storage medium having a computer program stored thereon to perform the method of claim 68 when said computer program is run by a computer.
